(19) United States
(12) Patent Application Publication
(10) Pub. No.: US 2015/0053553 A1
(43) Pub. Date: Feb. 26, 2015

(54) PLASMA PROCESSING APPARATUS

(71) Applicants: NISSIN ELECTRIC CO., LTD., KYOTO (JP); THE JAPAN STEEL WORKS, LTD., TOKYO (JP)

(72) Inventors: YASUNORI ANDO, KYOTO (JP); KAZUHIKO IRISAWA, KYOTO (JP); SHIGEAKI KISHIDA, KYOTO (JP); MASAKI CHIBA, KANAGAWA (JP)

(21) Appl. No.: 14/465,837

(22) Filed: Aug. 22, 2014

(30) Foreign Application Priority Data
Aug. 23, 2013 (JP) 2013-173160
Sep. 25, 2013 (JP) 2013-197785

(51) Int. Cl. C23C 14/34; C23C 16/46; H01J 37/32; C23C 16/455; C23C 16/509; C23C 16/52

(52) U.S. Cl. CPC C23C 14/3435; C23C 16/509; C23C 16/52; H01J 37/32155; H01J 37/32449; H01J 37/3211; C23C 16/45517; C23C 16/466; H01J 37/32183; H01J 37/32541; H01J 37/3266; H01J 2237/002; H01J 2237/18; H01J 2237/24564; H01J 2237/327; H01J 2237/3321; H01J 2237/3341
USPC 204/298.03; 118/723 I; 118/663; 156/345.28; 156/345.37; 156/345.48; 204/298.02; 204/298.09; 204/298.32; 204/298.39

(57) ABSTRACT

The antenna has a structure that the high frequency electrode is received in a dielectric case. The high frequency electrode has a go-and-return conductor structure that two electrode conductors are disposed close to and in parallel to each other with a gap therebetween to form a rectangular plate shape as a whole, and the two electrode conductors are connected by a conductor at an end in the longitudinal direction. A high frequency current flows in the two electrode conductors in opposite directions. A plurality of openings are formed on edges of the two electrode conductors on the side of the gap, and the openings are dispersed and arranged in the longitudinal direction of the high frequency electrode. The antenna is disposed in a vacuum container in a direction that a main surface of the high frequency electrode and a surface of the substrate are substantially perpendicular to each other.

### CROSS-REFERENCE TO RELATED APPLICATIONS

This application claims the priority benefit of Japan patent application serial no. 2013-173160, filed on Aug. 23, 2013, and Japan patent application serial no. 2013-197785, filed on Sep. 25, 2013. The entirety of each of the above-mentioned patent applications is hereby incorporated by reference herein and made a part of the specification.

### BACKGROUND OF THE INVENTION

1. Field of the Invention

The present invention relates to a plasma processing apparatus for performing processes, such as film formation by a plasma chemical vapor deposition (CVD) method, film formation by etching, ashing, and sputtering, etc., on a substrate with use of a plasma. More specifically, the present invention relates to an inductively-coupled-plasma (ICP) type plasma processing apparatus for generating a plasma by an induced electric field, which is generated by applying a high frequency current to an antenna, and processing the substrate using the plasma.

2. Description of Related Art

An example of this type of plasma processing apparatus is disclosed in Japanese Patent Publication No. 5018994 (Paragraphs 0012-0014, FIG. 1, and FIG. 3), in which the antenna includes a high frequency electrode having a structure that a plurality of openings are provided on the inner edges of two electrode conductors constituting a go-and-return conductor.

The conventional plasma processing apparatus is explained in brief with reference to FIG. 1 and FIG. 2. In order to simplify the illustration, a dielectric plate is not shown in FIG. 1. The high frequency electrode and the thickness of the substrate are omitted as well. These are illustrated in FIG. 2.

In a high frequency electrode 70 that constitutes an antenna 68, two rectangular plate-shaped electrode conductors 71 and 72 are arranged close to and in parallel to each other with a gap 74 therebetween so as to be positioned on the same plane that extends along a surface of a substrate 2, and a go-and-return conductor structure is formed by connecting the two electrode conductors 71 and 72 with a conductor (not shown in the figure) at one end in a longitudinal direction X and then a high frequency current I_{R} is applied to flow in the two electrode conductors 71 and 72 in opposite directions (because of the high frequency, the direction of the high frequency current I_{R} is inverted by time; the same hereinafter). The frequency of the high frequency current I_{R} is 13.56 MHz, for example.

Moreover, cutouts are respectively formed on edges of the two electrode conductors 71 and 72 on the side of the gap 74 to face each other across the gap 74. The opposite cutouts form a plurality of openings 77 that are dispersed and arranged along the longitudinal direction X of the high frequency electrode 70.

A dielectric plate 80 is disposed near a lower side of the high frequency electrode 70 in order to prevent the surface of the high frequency electrode 70 from being sputtered by charged particles (mainly ions) in the plasma 82.

A high frequency magnetic field is generated around the high frequency electrode 70 due to the high frequency current IR, and thereby an induced electric field is generated in the direction opposite to the high frequency current IR. In a vacuum container (not shown in the figure), electrons are accelerated by the induced electric field and gas near the antenna 68 (more specifically, near the lower side of the dielectric plate 80) is ionized to generate the plasma 82 near the lower side of the dielectric plate 80. The substrate 2 is disposed at a location facing a main surface of the high frequency electrode 70. The plasma 82 can diffuse to the vicinity of the substrate 2 for performing processes, such as the aforementioned film formation, on the substrate 2.

Effects achieved by the plasma processing apparatus are described in Japanese Patent Publication No. 5018994 as follows.

When a broader view is taken, the antenna 68 (more specifically, the high frequency electrode 70 thereof) forms the go-and-return conductor structure, and the high frequency current I_{R} flows in opposite directions in the two electrode conductor 71 and 72. Therefore, the effective inductance of the antenna 68 is reduced due to the mutual inductance existing between the electrode conductors 71 and 72. Accordingly, in comparison with a simply plate-shaped antenna, the potential difference generated between two end portions of the antenna 68 in the longitudinal direction X can be minimized and thereby the plasma potential can be kept low to improve the uniformity of the plasma density distribution in the longitudinal direction X of the antenna 68.

Further, regarding the high frequency current I_{R} flowing through the high frequency electrode 70, more specifically, the high frequency current I_{R} tends to flow through the end portions of the two electrode conductors 71 and 72 due to a skin effect. Among the above, when focusing on the edges of the two electrode conductors 71 and 72 on the side of the gap 74, the high frequency current I_{R} flows in opposite directions on the edges that are close to each other, and therefore the inductance (and the impedance) becomes smaller than that on the edges on the side opposite to the gap 74. Thus, more high frequency current I_{R} flows through the edges on the side of the gap 74 and the openings 77 formed thereon. The openings 77 perform the same function as coils dispersed and arranged in the longitudinal direction X of the antenna 68. As a result, the structure that includes multiple coils connected in series can be achieved by a simplified structure. Accordingly, a strong magnetic field can be generated near each opening 77 and the efficiency of plasma generation can be improved with the simplified structure.

### SUMMARY OF THE INVENTION

When forming a film on the substrate 2 using the conventional plasma processing apparatus of FIG. 1 and FIG. 2 and thoroughly measuring the film thickness distribution, it is found that the film thickness distribution in the longitudinal direction X of the antenna 68 shows a fluctuation corresponding to the arrangement of the openings 77, which poses a problem.

A result of measurement of the film thickness distribution is shown in FIG. 3. FIG. 3 shows results of measuring the film thickness at multiple points (some are represented by points a-f) of the substrate 2 that are respectively located right under the centers of the openings 77 and the centers between adjacent openings 77 on a central axis of the opening row in FIG. 1 when a mixture gas of silicon tetrafluoride gas (SiF₄) and nitrogen gas (N₂) is used as the source gas to form a fluorinated silicon nitride film (SiN:F) on the substrate 2. In this case, a pitch of the opening 77 was set to 48 mm, a diameter of each opening 77 was set to 40 mm, and a distance L₁ between the antenna 68 and the substrate 2 was set to 95 mm.

As shown by FIG. 3, thinner film thickness is formed at the location right under the center of each opening 77 (i.e. points b, d, f, etc.) and thicker film thickness is formed at the location right under the center between adjacent openings 77 (i.e. points a, c, e, etc.), and the film thickness distribution in the longitudinal direction X of the antenna 68 corresponds to the arrangement of the openings 77. Measurement at locations where the X is a negative value in FIG. 3 can be inferred from the above descriptions.

Because the high frequency current I_{R} or the plasma 82 can be easily affected by various objects that exist nearby, it is not easy to elucidate the above phenomenon theoretically, but it is considered that the fluctuation of the film thickness as shown in FIG. 3 is caused by the following.

(i) As described above, due to the skin effect and low impedance, more high frequency current I_{R} flows through the edges of the high frequency electrode 70 on the side of the gap 74 and peripheral portions of the openings 77. Therefore, the plasma generation effect caused by the high frequency current I_{R} flowing therethrough is strong. In particular, because opposite currents do not flow near each other at two end portions 79 (two end portions in a direction perpendicular to the longitudinal direction X; namely, two end portions in the Y direction in this example) of each opening 77, the plasma generation effect is strong, and dense plasma is generated at lower portions 84 (see FIG. 2) of the two end portions 79. In contrast thereto, the high frequency current I_{R} does not flow through the center of each opening 77, and thus the plasma generated at the lower portion 85 of the center is thin, which is a cause of the thinner film thickness at the points b, d, f, etc. of the substrate corresponding to the center. On the other hand, at the lower portions between adjacent openings 77, plasma thinner than that at the lower portions 84 of the two end portions 79 but denser than that at the lower portion 85 of the center of the opening 77 is generated, which is a cause of the larger film thickness at the points a, c, e, etc. of the substrate corresponding to the centers between adjacent openings 77. Due to the above, the plasma density in the longitudinal direction X of the antenna 68 varies corresponding to the arrangement of the openings 77 and results in the fluctuation of the film thickness distribution on the substrate 2.

(ii) Further, because the main surface of the high frequency electrode 70 that constitutes the antenna 68 and the substrate 2 are disposed to face each other like parallel plate electrodes, as the potential of the high frequency electrode 70 increases due to the high frequency current I_{R} applied to the high frequency electrode 70, a substantially uniform (a quasi-uniform) electric field is generated between the high frequency electrode 70 and the substrate 2. That is, like the example shown in FIG. 2, a nearly flat equipotential surface 86 is generated between the main surface of the high frequency electrode 70 and the substrate 2. In the case of the flat equipotential surface 86, it is difficult for the plasma 82 to diffuse in the lateral direction as the plasma 82 generated near the lower side of the antenna 68 (more specifically, the dielectric plate 80 thereof) diffuses to the side of the substrate 2. Hence, the difference of the plasma density caused by the above (i) is directly transferred to the substrate 2 easily. This is also a cause of the fluctuation of the film thickness distribution on the substrate 2.

It is considered that the increase of the distance L₁ between the antenna 68 and the substrate 2 can enhance the diffusion of the plasma 82 in the lateral direction before the plasma 82 reaches the substrate 2 so as to uniformize the plasma density near the substrate 2 and improve the uniformity of substrate processing. However, since the distance between the antenna 68 and the substrate 2 is increased, another problem such as increase of the size of the plasma processing apparatus occurs.

Therefore, the present invention is mainly directed to uniformizing the plasma density, which corresponds to the arrangement of the openings of the high frequency electrode that constitutes the antenna, near the substrate and improving the uniformity of substrate processing in the longitudinal direction of the antenna without increasing the distance between the antenna and the substrate.

A plasma processing apparatus of the present invention is an inductively-coupled plasma (ICP) type plasma processing apparatus that generates an induced electric field in a vacuum container to generate a plasma by applying a high frequency current to an antenna and processes a substrate by using the plasma. The antenna has a structure that receives a high frequency electrode in a dielectric case. The high frequency electrode has a go-and-return conductor structure that two electrode conductors, each having a rectangular plate shape, are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode. The antenna is disposed in the vacuum container in a direction that a main surface of the high frequency electrode that constitutes the antenna and a surface of the substrate are substantially perpendicular to each other.

The high frequency electrode may also have a structure that two electrode conductors, one having a rectangular plate shape and the other having a rod shape, are disposed close to and in parallel to each other with a gap therebetween to form a rectangular plate shape as a whole, and a plurality of cutouts are formed on an edge of the electrode conductor having the rectangular plate shape on the side of the gap to form a plurality of openings that are dispersed and arranged in the longitudinal direction of the high frequency electrode.

A planar shape of the antenna may be substantially straight or annular.

A dielectric tube may be disposed to traverse the dielectric case, or a side surface of the dielectric case may be recessed inward.

The antenna may have a structure that includes two high frequency electrodes received in the dielectric case, wherein a cooling pipe, in which a coolant flows, is held between the two high frequency electrodes for cooling the two high frequency electrodes, and distances respectively between an outer main surface of each high frequency electrode and an external surface of the dielectric case opposite thereto are made substantially equal to each other for the two high frequency electrodes.

The antenna may have a structure that includes two high frequency electrodes, wherein a cooling pipe, in which a coolant flows, is respectively attached to one main surface of each high frequency electrode for cooling the high frequency electrode, and the two high frequency electrodes are received in the dielectric case in a direction to put the cooling pipes on the inner sides, and distances respectively between an outer main surface of each high frequency electrode and an external surface of the dielectric case opposite thereto are made substantially equal to each other for the two high frequency electrodes.

The antenna may have a structure that cooling pipes, in which a coolant flows, are respectively attached to two main surfaces of the high frequency electrode for cooling the high frequency electrode, and distances respectively between the two main surfaces of the high frequency electrode and external surfaces of the dielectric case opposite thereto are substantially equal to each other.

The antenna may also have a structure that the high frequency electrode that constitutes the antenna includes a coolant passage therein, wherein a coolant flows in the coolant passage for cooling the high frequency electrode, and distances respectively between two main surfaces of the high frequency electrode and external surfaces of the dielectric case opposite thereto are substantially equal to each other.

The high frequency electrode that constitutes the antenna may include two electrode conductors that are respectively bent to form a U-shaped cross-section, and the antenna may have a structure that a cooling pipe, which is respectively held between each bent electrode conductor, is received in the dielectric case, wherein distances respectively between two outer main surfaces of the high frequency electrode and external surfaces of the dielectric case opposite thereto are substantially equal to each other.

Another plasma processing apparatus of the present invention is an inductively-coupled plasma (ICP) type plasma processing apparatus that generates an induced electric field in a vacuum container by applying a high frequency current to an antenna to generate a plasma and processes a substrate by using the plasma. The antenna has a structure that receives a high frequency electrode in a dielectric case. The high frequency electrode has a go-and-return conductor structure that two electrode conductors are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode. The antenna is disposed in the vacuum container in a direction that a main surface of the high frequency electrode that constitutes the antenna and a surface of the substrate are substantially perpendicular to each other. The antenna has a planar shape that is substantially straight, and a plurality of the antennas are disposed in parallel along the surface of the substrate. The plasma processing apparatus further includes a plurality of high frequency power supplies respectively supplying a high frequency power to each antenna; a plurality of magnetic field sensors respectively disposed at substantially the same location for each antenna and detecting an intensity of a magnetic field generated by each antenna; and a control device controlling the high frequency power outputted by each high frequency power supply responsive to outputs of the magnetic field sensors so as to make the outputs substantially equal to each other.

A plurality of electric field sensors may be disposed in place of the magnetic field sensors to respectively detect an intensity of an electric field generated by each antenna.

Instead of disposing multiple high frequency power supplies for respectively supplying the high frequency power to each antenna, a high frequency power supply and a distribution circuit may be disposed, wherein the high frequency power supply supplies the high frequency power to each antenna, and the distribution circuit distributes the high frequency power outputted by the high frequency power supply to each antenna, wherein a magnitude of the high frequency power distributed to each antenna is variable responsive to an external control signal.

According to an embodiment of the present invention, (a) since the antenna is disposed in the direction that the main surface of the high frequency electrode and the surface of the substrate are substantially perpendicular to each other, the plasma density is in an up-down direction with respect to the surface of the substrate. Thus, even if the plasma density varies corresponding to the center and two end portions of each opening of the high frequency electrode, the plasma is mixed to uniformize the plasma density easily while the plasma diffuses toward the side of the substrate. Moreover, because the equipotential surface between the high frequency electrode and the substrate is curved in a valley shape under the high frequency electrode when away from the substrate, the plasma easily diffuses in the lateral direction when diffusing toward the size of the substrate, and from this aspect, the plasma density corresponding to the arrangement of the openings of the high frequency electrode is easily uniformized near the substrate.

(b) As a result, even though the distance between the antenna and the substrate is not increased, the plasma density corresponding to the arrangement of the openings of the high frequency electrode that constitutes the antenna can be uniformized near the substrate to improve the uniformity of substrate processing in the longitudinal direction of the antenna. Furthermore, since it is not required to increase the distance between the antenna and the substrate, increase of the sizes of the vacuum container and the plasma processing apparatus can be avoided.

According to another embodiment of the present invention, the antenna is disposed in the direction that the main surface of the high frequency electrode and the surface of the substrate are substantially perpendicular to each other. Thus, this embodiment achieves the same effects as the above embodiment. In addition, because one of the two electrode conductors that constitute the high frequency electrode is rod-shaped, protrusion dimensions of the antenna in the vacuum container can be reduced, compared with the rectangular plate shape. As a result, the sizes of the vacuum container and the plasma processing apparatus can be further reduced.

Another embodiment of the present invention further achieves the following effects. That is, because multiple antennas, each having the substantially straight planar shape, are disposed in parallel to each other along the surface of the substrate, a plasma of a larger area is generated for processing a substrate of a larger area. Moreover, all the grounding points of the high frequency electrodes are disposed on the side of the substrate. The potential variation on the side of the grounding point of the high frequency electrode is smaller than the potential variation on the side of the power feeding point, and the electrode conductor with less potential variation is disposed on the side of the substrate. Thus, non-uniformity of substrate processing resulting from the potential variation of the high frequency electrode can be suppressed.

Another embodiment of the present invention further achieves the following effects. That is, because multiple antennas, each having the substantially straight planar shape, are disposed in parallel to each other along the surface of the substrate, a plasma of a larger area is generated for processing a substrate of a larger area. In addition, because the power feeding points and the grounding points of the high frequency electrodes are disposed alternately on multiple antennas, any imbalance that may occur in the plasma distribution in the longitudinal direction of each antenna due to the manner of arranging the power feeding points and the grounding points is offset easily. As a result, the uniformity of large-area plasma can be improved.

Another embodiment of the present invention further achieves the following effects. That is, the plasma density of the two end regions in the parallel direction of the antennas usually tends to be lower than the plasma density of the other regions. Regarding this, the interval of the two end regions in the parallel direction of the antennas is made smaller than the interval of the other regions according to the present invention. Thus, the plasma density in the two end regions can be increased to compensate for the low plasma density, thereby improving the plasma uniformity in the parallel direction of the antennas.

Another embodiment of the present invention further achieves the following effects. That is, because annular plasma is generated near the antenna corresponding to the planar shape of the antenna, the processing for a substrate or a sputter target having a circular or nearly circular planar shape can be performed easily.

Another embodiment of the present invention further achieves the following effects. That is, a strong magnetic field is generated near each opening of the high frequency electrode that constitutes the antenna and the dielectric tube is disposed to pass through the opening. Therefore, dense plasma can be generated in the dielectric tube using the strong magnetic field. As a result, the efficiency of plasma generation and utilization of the high frequency power can be improved.

Another embodiment of the present invention further achieves the following effects. That is, a strong magnetic field is generated near each opening of the high frequency electrode that constitutes the antenna and the side surfaces of the portions of the dielectric case, which correspond to the openings, are recessed inward to be closer to the openings. Thus, dense plasma can be generated near the recessed portions using the strong magnetic field. As a result, the efficiency of plasma generation and utilization of the high frequency power can be improved.

Another embodiment of the present invention further achieves the following effects. That is, a strong magnetic field is generated near each opening of the high frequency electrode that constitutes the antenna and the side surface of the region of the dielectric case, which includes the portion corresponding to the openings, is recessed inward to be closer to the openings. Thus, dense plasma can be generated near the recessed portion using the strong magnetic field. As a result, the efficiency of plasma generation and utilization of the high frequency power can be improved.

Another embodiment of the present invention further achieves the following effects. That is, the antenna includes two high frequency electrodes and has the structure that receives the cooling pipe, held between the two high frequency electrodes, in the dielectric case. Moreover, the distances respectively between the outer main surfaces of the high frequency electrodes and the external surfaces of the dielectric case opposite thereto are substantially equal to each other for the two high frequency electrodes. Thus, the density of the plasma generated by using the antenna can be uniformized on the left and right sides of the antenna.

(c) As a result, the uniformity of substrate processing in the left-right direction of the antenna can be enhanced as well. Furthermore, since it is not required to increase the distance between the antenna and the substrate, increase of the sizes of the vacuum container and the plasma processing apparatus can be avoided.

(d) In other words, according to the present invention, the uniformity of substrate processing in the longitudinal direction of the antenna can be improved as described above, and the uniformity of substrate processing in the left-right direction of the antenna can be improved as well. By combining the two effects, the uniformity of the processing in two dimensions of the substrate surface can be improved even without increasing the distance between the antenna and the substrate.

Another embodiment of the present invention further achieves the following effects. That is, the antenna has a structure that includes two high frequency electrodes, wherein a cooling pipe is respectively attached to one main surface of each high frequency electrode, and the two high frequency electrodes are received in the dielectric case in a direction to put the cooling pipes on the inner sides. Moreover, the distances respectively between the outer main surface of each high frequency electrode and the external surface of the dielectric case opposite thereto are substantially equal to each other for the two high frequency electrodes. Thus, the density of the plasma generated by using the antenna can be uniformized on the left and right sides of the antenna.

As a result, effects of the aforementioned (c) and (d) of the present invention can be achieved.

Another embodiment of the present invention further achieves the following effects. That is, the antenna has the structure that cooling pipes are respectively attached to two main surfaces of the high frequency electrode. Moreover, the distances respectively between the two main surfaces of the high frequency electrode and the external surfaces of the dielectric case opposite thereto are substantially equal to each other. Thus, the density of the plasma generated by using the antenna can be uniformized on the left and right sides of the antenna.

As a result, effects of the aforementioned (c) and (d) of the present invention can be achieved.

Another embodiment of the present invention further achieves the following effects. That is, the antenna includes the coolant passage in the high frequency electrode that constitutes the antenna, and the distances respectively between two main surfaces of the high frequency electrode and the external surfaces of the dielectric case opposite thereto are substantially equal to each other. Thus, the density of the plasma generated by using the antenna can be uniformized on the left and right sides of the antenna.

As a result, effects of the aforementioned (c) and (d) of the present invention can be achieved.

According to another embodiment of the present invention, the antenna is disposed in the direction that the main surface of the high frequency electrode and the surface of the substrate are substantially perpendicular to each other. Thus, this embodiment achieves the same effects as the aforementioned (a) and (b).

Furthermore, the high frequency electrode that constitutes the antenna includes two electrode conductors that are respectively bent to form a U-shaped cross-section, and the antenna has the structure that a cooling pipe, which is respectively held between each bent electrode conductor, is received in the dielectric case. Moreover, the distances respectively between two outer main surfaces of the high frequency electrode and the external surfaces of the dielectric case opposite thereto are substantially equal to each other. Therefore, the density of the plasma generated by using the antenna can be uniformized on the left and right sides of the antenna. As a result, effects of the aforementioned (c) and (d) of the present invention can be achieved.

(e) In addition, because the two electrode conductors have the bent structure as described above, the angular portion is reduced, and the electric field concentration around the high frequency electrode during application of the high frequency power can be reduced. As a result, abnormal electrical discharge can be suppressed.

According to another embodiment of the present invention, the antenna is disposed in the direction that the main surface of the high frequency electrode and the surface of the substrate are substantially perpendicular to each other. Thus, this embodiment achieves the same effects as the aforementioned (a) and (b).

What is more, because multiple antennas, each having the substantially straight planar shape, are disposed in parallel to each other along the surface of the substrate, a plasma of a larger area can be generated for processing a substrate of a larger area.

In addition, the high frequency power outputted by each high frequency power supply can be controlled responsive to the outputs of multiple magnetic field sensors to make the outputs substantially equal to each other, and thereby the intensity of the magnetic field generated by each antenna can be uniformized. Thus, the plasma uniformity in the parallel direction of the antennas can be improved.

(f) As a result, according to the present invention, the uniformity of substrate processing in the longitudinal direction of the antenna can be improved as described above, and the plasma uniformity in the parallel direction of the antennas can be improved as well for enhancing the uniformity of substrate processing. Hence, by combining the two effects, the uniformity of processing in two dimensions of the substrate surface can be enhanced without increasing the distance between the antenna and the substrate.

According to another embodiment of the present invention, the antenna is disposed in the direction that the main surface of the high frequency electrode and the surface of the substrate are substantially perpendicular to each other. Thus, this embodiment achieves the same effects as the aforementioned (a) and (b).

What is more, because multiple antennas, each having the substantially straight planar shape, are disposed in parallel to each other along the surface of the substrate, a plasma of a larger area can be generated for processing a substrate of a larger area.

In addition, the high frequency power outputted by each high frequency power supply can be controlled responsive to the outputs of multiple electric field sensors to make the outputs substantially equal to each other, and thereby the intensity of the electric field generated by each antenna can be uniformized. Thus, the plasma uniformity in the parallel direction of the antennas can be improved.

As a result, effects of the aforementioned (f) of the present invention can be achieved.

According to another embodiment of the present invention, the antenna is disposed in the direction that the main surface of the high frequency electrode and the surface of the substrate are substantially perpendicular to each other. Thus, this embodiment achieves the same effects as the aforementioned (a) and (b).

What is more, because multiple antennas, each having the substantially straight planar shape, are disposed in parallel to each other along the surface of the substrate, a plasma of a larger area can be generated for processing a substrate of a larger area.

In addition, the magnitude of the high frequency power distributed to each antenna by the distribution circuit can be controlled responsive to the outputs of multiple magnetic field sensors to make the outputs substantially equal to each other, and thereby the intensity of the magnetic field generated by each antenna can be uniformized. Thus, the plasma uniformity in the parallel direction of the antennas can be improved.

As a result, effects of the aforementioned (f) of the present invention can be achieved.

According to another embodiment of the present invention, the antenna is disposed in the direction that the main surface of the high frequency electrode and the surface of the substrate are substantially perpendicular to each other. Thus, this embodiment achieves the same effects as the aforementioned (a) and (b).

What is more, because multiple antennas, each having the substantially straight planar shape, are disposed in parallel to each other along the surface of the substrate, a plasma of a larger area can be generated for processing a substrate of a larger area.

In addition, the magnitude of the high frequency power distributed to each antenna by the distribution circuit can be controlled responsive to the outputs of multiple electric field sensors to make the outputs substantially equal to each other, and thereby the intensity of the electric field generated by each antenna can be uniformized. Thus, the plasma uniformity in the parallel direction of the antennas can be improved.

As a result, effects of the aforementioned (f) of the present invention can be achieved.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 is a schematic perspective view showing a portion of an antenna and a substrate of the conventional plasma processing apparatus, and a dielectric plate is omitted.

FIG. 2 is a schematic view exemplifying an equipotential surface between the antenna and the substrate in the apparatus of FIG. 1, and the dielectric plate is also shown.

FIG. 3 is a diagram exemplifying a result of measuring the film thickness distribution of a film formed on the substrate using the apparatus of FIG. 1.

FIG. 4 is a schematic cross-sectional view showing an embodiment of a plasma processing apparatus of the present invention.

FIG. 5 is a schematic cross-sectional view showing one antenna and components around the antenna in the apparatus of FIG. 4 laterally.

FIG. 6 is a schematic front view of a high frequency electrode that constitutes the antenna of FIG. 5, and a cooling pipe is omitted.

FIG. 7 is a schematic perspective view showing a portion of an antenna and a substrate of a plasma processing apparatus of an embodiment for film thickness measurement, and a dielectric case is omitted.

FIG. 8 is a schematic view exemplifying an equipotential surface between one antenna and the substrate in the apparatus of FIG. 7, and the dielectric case is also shown.

FIG. 9 is a diagram exemplifying a result of measuring the film thickness distribution of a film formed on the substrate using the apparatus of FIG. 7.

FIG. 10 is a schematic perspective view showing an example of arranging a plurality of antennas in parallel, and the dielectric case is omitted.

FIG. 11 is a schematic perspective view showing another example of arranging a plurality of antennas in parallel, and the dielectric case is omitted.

FIG. 12 is a schematic front view partially showing another example of the high frequency electrode.

FIG. 13 is a schematic plan view showing an example of an annular antenna, and the dielectric case is omitted.

FIG. 14 is a schematic plan view showing another example of the annular antenna, and the dielectric case is omitted.

FIG. 15A and FIG. 15B is a schematic view showing an example of disposing a dielectric tube in the dielectric case that constitutes the antenna, wherein FIG. 15A is a longitudinal cross-sectional view and FIG. 15B is a right side view.

FIG. 16A and FIG. 16B is a schematic view showing an example of partially recessing the dielectric case that constitutes the antenna, wherein FIG. 16A is a longitudinal cross-sectional view and FIG. 16B is a right side view.

FIG. 17A and FIG. 17B is a schematic view showing an example of continuously recessing the dielectric case that constitutes the antenna, wherein FIG. 17A is a longitudinal cross-sectional view and FIG. 17B is a right side view.

FIG. 18 is a schematic cross-sectional view showing another embodiment of the plasma processing apparatus of the present invention.

FIG. 19 is a schematic enlarged cross-sectional view of one antenna in the apparatus of FIG. 18.

FIG. 20 is a schematic cross-sectional view showing another example of the antenna corresponding to FIG. 19.

FIG. 21 is a schematic cross-sectional view showing yet another example of the antenna corresponding to FIG. 19.

FIG. 22 is a schematic cross-sectional view showing yet another example of the antenna corresponding to FIG. 19.

FIG. 23 is a schematic cross-sectional view showing the antenna of FIG. 22 in the direction of arrow I-I as well as a vacuum container, etc., corresponding to FIG. 5.

FIG. 24 is a schematic cross-sectional view showing yet another example of the antenna corresponding to FIG. 19.

FIG. 25 is a schematic view exemplifying an apparatus in which a plurality of antennas are arranged in parallel, and the dielectric case of each antenna is omitted.

FIG. 26 is a schematic enlarged side view showing one antenna in the apparatus of FIG. 25 and components around a magnetic field sensor in the case where the magnetic field sensor serves as the sensor, and the dielectric case is omitted.

FIG. 27 is a schematic cross-sectional view taken along the line J-J of FIG. 26, and the dielectric case is also shown.

FIG. 28 is a schematic enlarged side view showing one antenna in the apparatus of FIG. 25 and components around an electric field sensor in the case where the electric field sensor serves as the sensor, and the dielectric case is omitted.

FIG. 29 is a schematic cross-sectional view taken along the line K-K of FIG. 28, and the dielectric case is also shown.

FIG. 30 is a schematic view exemplifying another apparatus in which a plurality of antennas are arranged in parallel, and the dielectric case of each antenna is omitted.

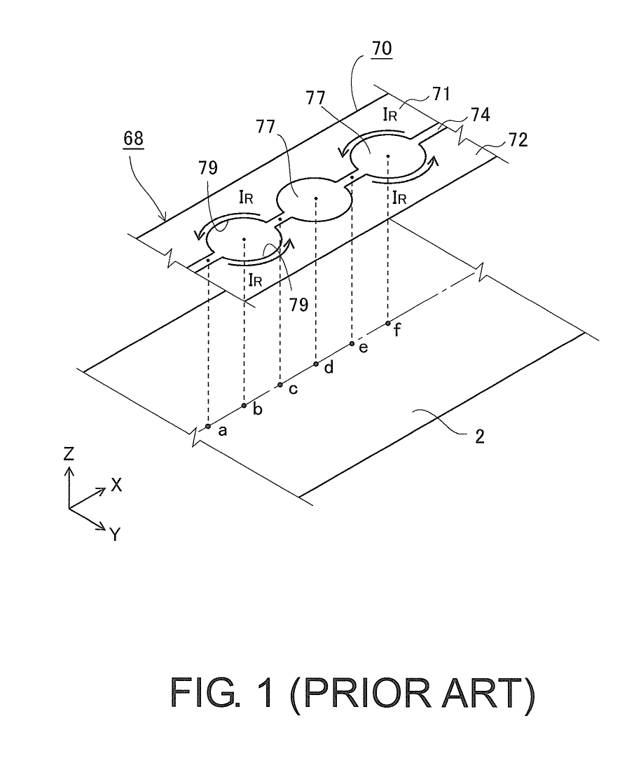

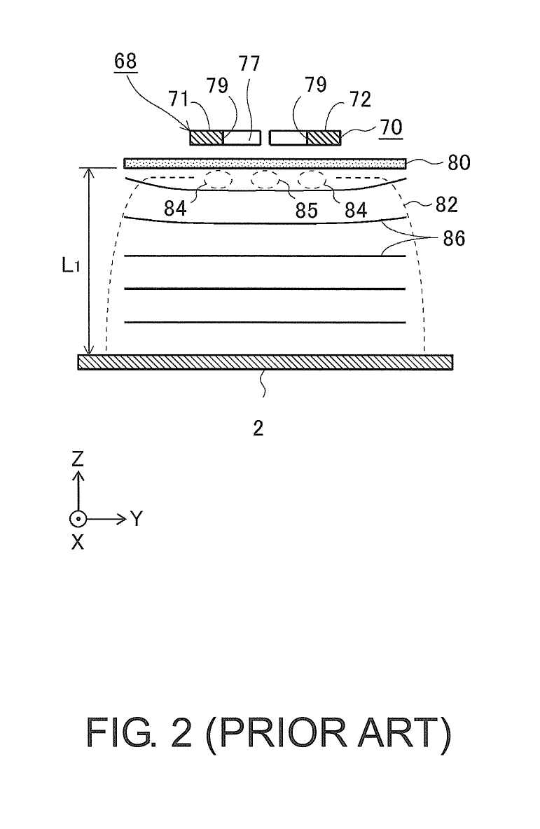

### DESCRIPTION OF THE EMBODIMENTS

### (1) An Embodiment of the Plasma Processing Apparatus

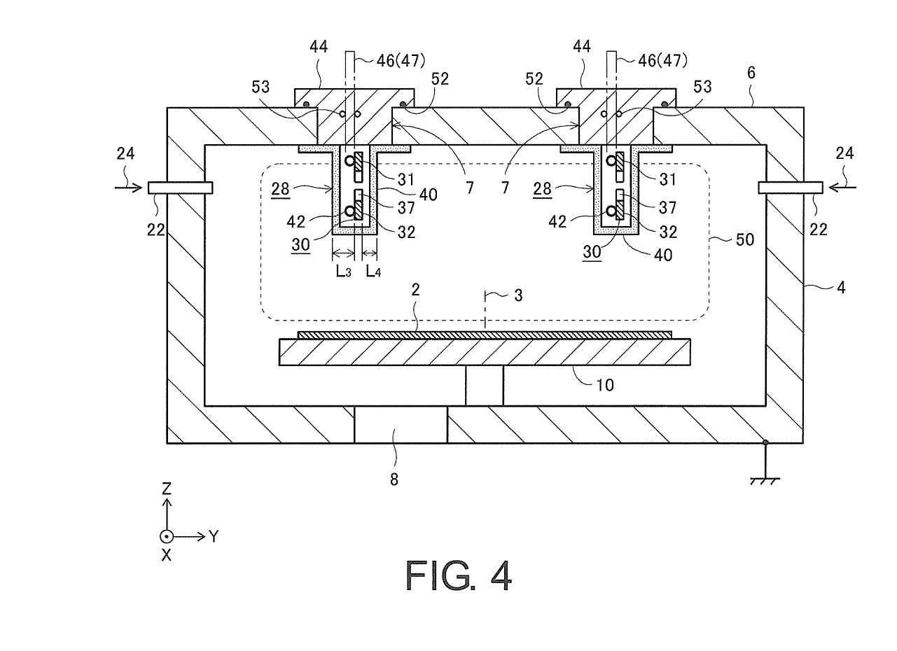

An embodiment of the plasma processing apparatus of the present invention is described below with reference to FIG. 4 to FIG. 6.

An X direction, a Y direction, and a Z direction that are orthogonal to one another at one point are respectively shown in the figures to represent the direction of an antenna 28, etc. The Z direction is parallel to a perpendicular line 3 standing on a surface of a substrate 2. The Y direction is orthogonal to the perpendicular line 3. These directions may be respectively referred to as an up-down direction Z and a left-right direction Y to simplify the descriptions. The X direction is orthogonal to the perpendicular line 3, and the X direction is a longitudinal direction of the antenna 28. For example, the X direction and the Y direction are horizontal directions while the Z direction is a vertical direction. However, the present invention is not limited thereto.

This apparatus is an inductively-coupled plasma (ICP) type plasma processing apparatus, wherein an induced electric field is generated in a vacuum container 4 by applying a high frequency current I_{R} from a high frequency power supply 60 to the antenna 28, so as to generate a plasma 50, and the plasma 50 is used to process the substrate 2.

In this embodiment, the antenna 28 has a planar shape that is substantially straight in the X direction. In the present application, the wording “substantially straight” not only represents “a straight status” according to the plan meaning but also represents “a nearly straight status”.

In the vacuum container 4, a holder 10 is disposed for holding the substrate 2.

The substrate 2 can be a substrate used in display devices such as liquid crystal displays and organic electroluminescent displays, a flexible substrate used in flexible displays, or a substrate used in semiconductor devices such as solar cells, for example. Nevertheless, the present invention is not limited thereto.

A planar shape of the substrate 2 can be circular or quadrilateral, for example, but the planar shape is not particularly restricted in the present invention.

The processing applied on the substrate 2, for example, includes forming a film by a plasma CVD (chemical vapor deposition) process, etching, ashing, sputtering, or the like.

The plasma processing apparatus is also called a plasma CVD apparatus when used for the plasma CVD process, a plasma etching apparatus for etching process, a plasma ashing apparatus for ashing process, and a plasma sputtering apparatus for sputtering process.

The plasma processing apparatus includes the vacuum container 4 which is made of metal, for example, and the interior of the vacuum container 4 is vacuumed through a vacuum exhaust port 8.

A gas 24 is introduced into the vacuum container 4 through a gas inlet tube 22. In this embodiment, a plurality of the gas inlet tubes 22 are respectively disposed in the longitudinal direction X of each antenna 28.

The gas 24 may be any gas which is appropriate to the content of the processing applied on the substrate 2. For example, if the film formation on the substrate 2 is carried out by performing the plasma CVD process, the gas 24 is a source gas. More specifically, if the source gas is SiH4, a Si film is formed on the surface of the substrate 2; if the source gas is SiH4+O2, a SiO2 film is formed on the surface of the substrate 2; if the source gas is SiH4+NH3, a SiN:H film (hydrogenated silicon nitride film) is formed on the surface of the substrate 2; and if the source gas is SiF₄+N₂, a SiN:F film (fluorinated silicon nitride film) is foamed on the surface of the substrate 2, respectively.

In this embodiment, two antennas 28 are provided. However, the number of the antennas 28 may be one or more. Each of the antennas 28 has a structure, in which the high frequency electrode 30 is received in the dielectric case (i.e. a case made of dielectric) 40. With the dielectric case 40, sputtering on the surface of the high frequency electrode 30 in the dielectric case 40, caused by charged particles (mainly ions) in the plasma 50, can be prevented.

The dielectric case 40 is formed of quartz, alumina, ceramics such as silicon carbide, or a silicon plate, for example.

Then, the antenna 28 is disposed in the vacuum container 4 and arranged in a direction that a main surface (i.e. a larger surface of the plate) of the high frequency electrode 30 constituting the antenna 28 and the surface of the substrate 2 are substantially perpendicular to each other. In the present application, the wording “substantially perpendicular” not only represents “a perpendicular status” according to the plan meaning but also represents “a nearly perpendicular status”.

According to this embodiment, two opening portions 7 respectively corresponding to the length of the antenna 28 are formed in a ceiling surface 6 of the vacuum container 4, and the antenna 28 is respectively disposed at the bottom of each opening portion 7. According to this embodiment, the dielectric case 40 of each antenna 28 is fixed to an inner surface of the ceiling surface 6.

Each opening portion 7 is capped with a cover plate 44, and a packing 52 for vacuum sealing is disposed between each cover plate 44 and the ceiling surface 6. Feedthroughs 46 and 47, which will be described later, are formed to pass through the cover plate 44, and a packing 53 for vacuum sealing is provided at a through portion thereof. The cover plate 44 may be made of a dielectric such as quartz, alumina, etc., for example, or the cover plate 44 may be made of metal to ensure electrical isolation of the through portions of the feedthroughs 46 and 47. If the cover plate 44 is made of metal, leakage of the high frequency from the antenna 28 to the outside through the opening portion 7 can be easily prevented.

In this embodiment, the packing for vacuum sealing is not disposed between the dielectric case 40 of each antenna 28 and the ceiling surface 6. Accordingly, like the outside, the inside of each dielectric case 40 also has the atmosphere of the vacuum container 4. Even so, plasma is not generated in the dielectric case 40. The reason is that the space in the dielectric case 40 is too small to provide an electron traveling distance for generating plasma. In other words, the plasma 50 is generated outside each dielectric case 40. However, the packing for vacuum sealing may be disposed between the dielectric case 40 and the vacuum container 4 (more specifically, the ceiling surface 6) such that the inside of the dielectric case 40 is on the atmosphere side. In that case, the packing 53 is not required. The same applies to the other embodiments that are described later.

In this embodiment, the high frequency electrode 30 that constitutes each antenna 28 has a structure that two electrode conductors 31 and 32, each having a long rectangular plate shape in the X direction, are disposed close to and in parallel to each other with the gap 34 therebetween, so as to form a rectangular plate shape as a whole. More specifically, the two electrode conductors 31 and 32 are arranged close to and in parallel to each other with the gap 34 therebetween in a way that the two electrode conductors 31 and 32 are located on the same plane (i.e. on the same plane that is parallel to an XZ plane in this embodiment) perpendicular to the surface of the substrate 2. The two electrode conductors 31 and 32 are connected by a conductor 33 at one end in the longitudinal direction X. Accordingly, each high frequency electrode 30 has a go-and-return conductor structure. The conductor 33 is formed integrally with the two electrode conductors 31 and 32 in this embodiment, but the conductor 33 may be a separate component. In addition, a cooling pipe 42, which will be described later, may also serve as the conductor 33. The same applies to the other embodiments of the antenna 28 which will be described later.

A material of the electrode conductors 31 and 32 and the conductor 33 may be copper (more specifically, oxygen free copper) or aluminum, for example, but is not limited to the foregoing.

High frequency power provided by the high frequency power supply 60 through a matching circuit 62 is supplied to the two electrode conductors 31 and 32 that constitute each high frequency electrode 30 via the feedthroughs 46 and 47, so as to generate the high frequency current I_{R} (go-and-return current) flowing in opposite directions in the two electrode conductors 31 and 32 (as described above, because of the high frequency, the direction of the high frequency current I_{R} is inverted by time; the same applies to the other embodiments). To be more specific, an end of the electrode conductor 31 serving as one part of the go-and-return conductor structure, which is opposite to the side of the conductor 33, is a power feeding point 48 of the high frequency power (i.e. a point on the side connecting to the high frequency power supply 60; the same hereinafter), and an end of the electrode conductor 32 as the other part, which is opposite to the side of the conductor 33, is a grounding point 49 (i.e. a point on the side connecting to the ground; the same hereinafter).

In this embodiment, the high frequency power is supplied in parallel to the high frequency electrodes 30 of multiple antennas 28 from the common high frequency power supply 60 and matching circuit 62. However, the high frequency power may be supplied to the high frequency electrodes 30 from separate high frequency power supplies 60 and matching circuits 62. The same applies to the other embodiments that will be described later.

Generally, a frequency of the high frequency power outputted by the high frequency power supply 60 is 13.56 MHz, for example, but is not limited thereto.

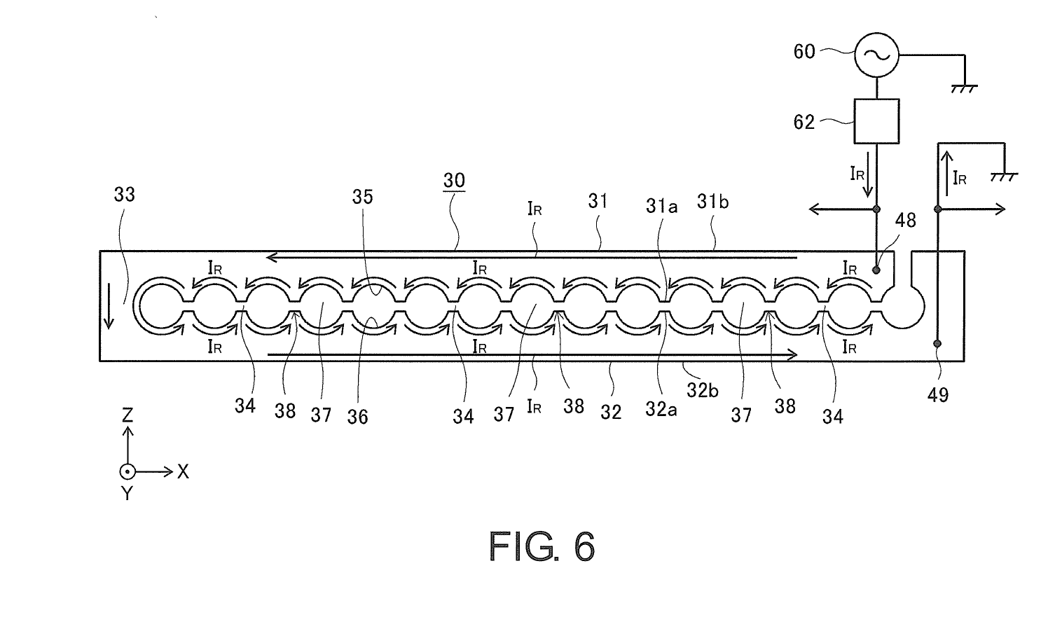

Moreover, cutouts 35 and 36 are respectively formed on edges 31a and 32a (see FIG. 6) of the two electrode conductors 31 and 32 that constitute each high frequency electrode 30 on the side of the gap 34 (i.e. the inner side) to face each other across the gap 34. Each pair of opposite cutouts 35 and 36 forms an opening 37, and a plurality of openings 37 are dispersed and arranged in the longitudinal direction X of the antenna 28. The number of the openings 37 is not restricted by the disclosure of the figures. The same applies to the other embodiments of the antenna 28 that will be described later.

Preferably, the cutouts 35 and 36 are formed symmetrically with the gap 34 as a center. A shape of the opening 37 may be circular, as shown in the figures, or may be rectangular.

As illustrated in this embodiment, the cooling pipe 42, avoiding the openings 37, may be attached to the high frequency electrode 30 of each antenna 28 by a bonding means, such as soldering. The cooling pipe 42 is a pipe made of metal, for example. The same applies to the other embodiments which will be described later. A coolant (e.g. cooling water) is supplied to flow in the cooling pipe 42 through the feedthroughs 46 and 47. In other words, the feedthroughs 46 and 47 are used for both supplying the high frequency power and the coolant.

By applying the high frequency current I_{R} to the high frequency electrode 30 that constitutes each antenna 28 as described above, a high frequency magnetic field is generated around each high frequency electrode 30, and thereby an induced electric field is generated in an opposite direction to the high frequency current IR. In the vacuum container 4, electrons are accelerated by the induced electric field to ionize the gas 24 near the antenna 28, so as to generate the plasma 50 near the outer side of the dielectric case 40. The plasma 50 diffuses to the vicinity of the substrate 2 to allow processing, such as the aforementioned film formation, on the substrate 2.

The plasma processing apparatus of this embodiment also has the structure that the high frequency electrode 30 constituting each antenna 28 is a go-and-return conductor structure when viewed as a whole and multiple openings 37 are dispersed and arranged on each high frequency electrode 30 in the longitudinal direction X. Therefore, the plasma processing apparatus of this embodiment achieves the same effects as the conventional plasma processing apparatus mentioned above.

In other words, the antenna 28 (more specifically, the high frequency electrode 30) has a go-and-return conductor structure when viewed as a whole and the high frequency current I_{R} flows in opposite directions in the two electrode conductors 31 and 32. Hence, an effective inductance of the antenna 28 is reduced due to a mutual inductance existing between the electrode conductors 31 and 32.

To explain this in detail, a total impedance Z_{T} of go-and-return conductors disposed close to and in parallel to each other is represented by the following equation, which is also described in books regarding electrical theories as differential connection. Here, in order to simplify the explanation, a resistance of each conductor is collectively represented by R, a self inductance is collectively represented by L, and a mutual inductance between the two conductors is represented by M.

Z_{T}=2R+j2(L−M) [Equation 1]

An inductance L_{T} in the total impedance Z_{T} is represented by the following equation. Like the inductance L_{T}, a combination of the self inductance and the mutual inductance is referred to as the effective inductance in this specification.

L_{T}=2(L−M) [Equation 2]

As known from the above equation, the effective inductance L_{T} of the go-and-return conductors is reduced due to of the mutual inductance M, and the total impedance Z_{T} is also reduced. This principle also applies to the antenna 28 that has the go-and-return conductor structure.

As a result of the reduction of the effective inductance of the antenna 28 based on the above principle, a potential difference that occurs between two ends of the antenna 28 in the longitudinal direction X can be reduced as compared with a simple plate-shaped antenna. Thus, the plasma potential can be reduced and the uniformity of plasma density distribution in the longitudinal direction X of the antenna 28 can be improved.

As a result of reduction of the plasma potential, energy of the charged particles emitted to the substrate 2 from the plasma 50 can be suppressed. Thus, for example, the damage caused to the firm formed on the substrate 2 can be reduced to improve the film quality. Further, even in the case of a long antenna 28, the potential of the antenna 28 and the plasma potential can both be reduced for the above reason. Therefore, the antenna 28 can be easily made longer corresponding to the increase of the size of the substrate 2.

Since the uniformity of plasma density distribution in the longitudinal direction X of the antenna 28 is improved, the uniformity of substrate processing in the longitudinal direction X of the antenna 28 can also be increased. For example, the uniformity of film thickness distribution in the longitudinal direction X of the antenna 28 can be enhanced.

Moreover, regarding details of the high frequency current I_{R} flowing through the high frequency electrode 30, as illustrated by the embodiment of FIG. 6, the high frequency current I_{R} has a tendency to flow mainly through edge portions of the two electrode conductors 31 and 32 due to a skin effect. Among them, when focusing on the edges 31a and 32a of the two electrode conductors 31 and 32 on the side of the gap 34, because the high frequency current I_{R} flows in opposite directions on the edges that are close to each other, the inductance (and the impedance) is smaller compared with edges 31b and 32b on the side opposite to the gap 34. Therefore, more high frequency current I_{R} flows along the edges on the side of the gap 34 and the openings 37 formed thereon. As a result, the openings 37 have the same function as coils dispersed in the longitudinal direction X of the antenna 28. Thus, the present invention achieves a structure having multiple coils connected in series by a simple structure. Accordingly, with the simple structure, a strong magnetic field can be generated near each opening 37 and the efficiency of plasma generation can be increased.

As the above embodiment, even though the cooling pipe 42 is attached to the high frequency electrode 30 by soldering, etc., the inductance (and the impedance) at the edges on the side of the gap 34 is small and more high frequency current I_{R} flows through the edges on the side of the gap 34 and the openings 37 formed thereon, as described above. Thus, generation of the strong magnetic field near the openings 37 is not hindered. The same applies to the other embodiments that will be described later.

Furthermore, different from the aforementioned conventional technology, when the plasma processing apparatus of this embodiment is used, the plasma density corresponding to the arrangement of the openings 37 of the high frequency electrode 30 that constitutes the antenna 28 can be uniformized near the substrate 2 to improve the uniformity of substrate processing in the longitudinal direction X of the antenna 28 even without increasing the distance between the antenna 28 and the substrate 2. The above is explained in detail with reference to the result of film thickness measurement below.

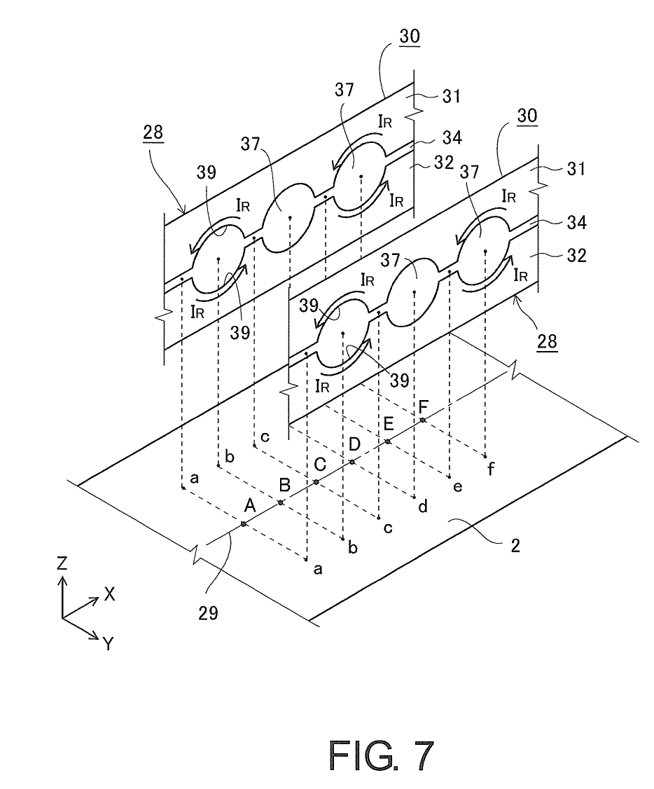

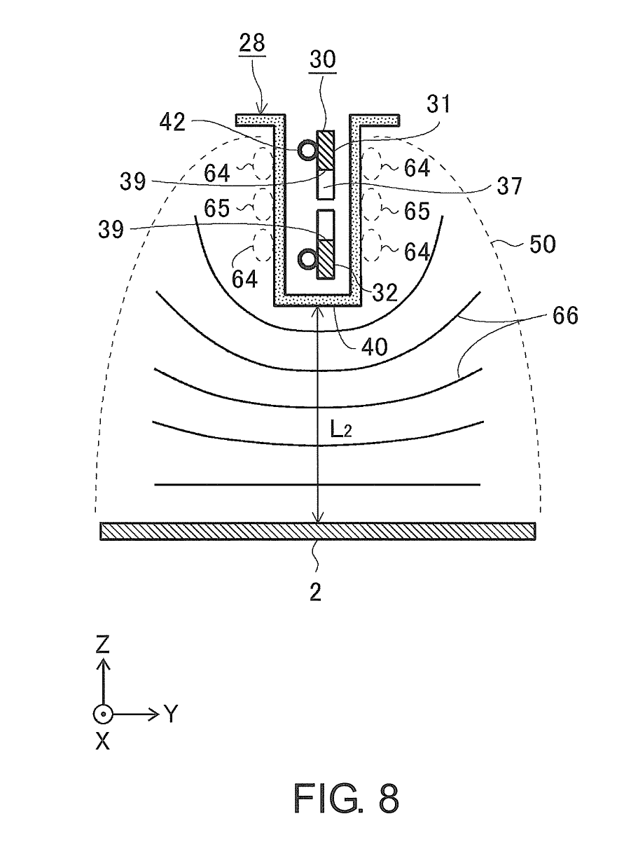

The plasma processing apparatus having the structure shown in FIG. 7 and FIG. 8 was used for film thickness measurement. FIG. 7 and FIG. 8 are simplified figures of FIG. 4. In order to simplify the illustration, the dielectric case is omitted from FIG. 7. The high frequency electrode and the thickness of the substrate are omitted as well. These are illustrated in FIG. 8.

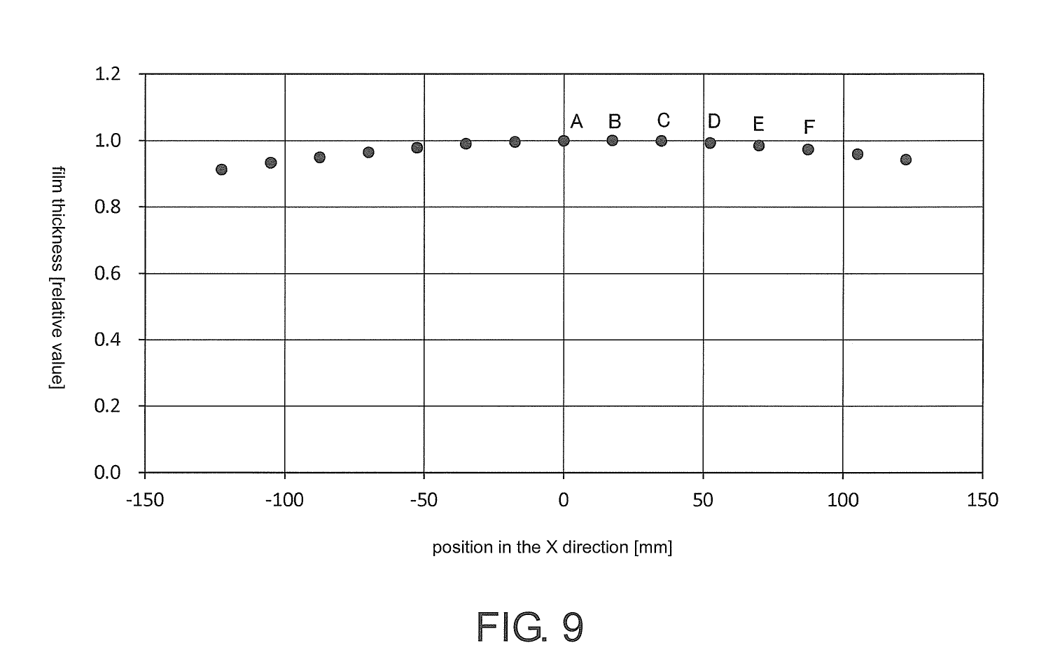

FIG. 9 exemplifies the result of measuring the film thickness distribution of a film formed on the substrate 2 using the plasma processing apparatus. FIG. 9 shows results of measuring the film thickness at multiple points (some are represented by points A-F) on a central axis 29 between two antennas 28 in a vertical arrangement shown in FIG. 7 when a mixture gas of silicon tetrafluoride gas (SiF₄) and nitrogen gas (N₂) is used as the source gas to form a fluorinated silicon nitride film (SiN:F) on the substrate 2. The points A-F on the central axis 29 are central points respectively corresponding to points (some are represented by points a-f) on the substrate 2 in the Y direction, wherein the points a-f are respectively located right under the centers of the openings 37 and the centers of the adjacent openings 37 of the high frequency electrodes 30 that constitute the antennas 28. Measurement at locations where the X value is greater than that of the point F of FIG. 9 or is a negative value can be inferred from the above descriptions.

Here, a pitch of the opening 37 was set to 35 mm, a diameter of each opening 37 was set to 30 mm, a gap between two antennas 28 was set to 125 mm, and a distance L₂ between the antenna 28 and the substrate 2 was set to 100 mm.

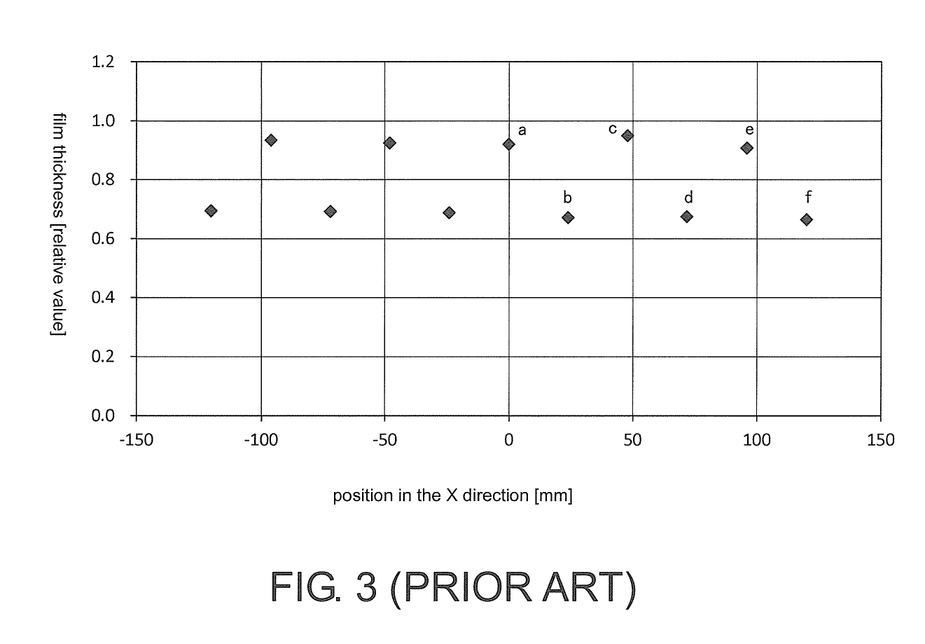

According to FIG. 9, the fluctuation of the conventional technology (see FIG. 3) does not occur, and the film thickness in the longitudinal direction X of the antenna 28 has an uniform film thickness distribution.

It is considered that the favorable result is obtained due to the following functions.

(i) In this embodiment, the antenna 28 is disposed in the direction that the main surface of the high frequency electrode 30 and the surface of the substrate 2 are substantially perpendicular to each other. Thus, for the same reasons as the conventional technology, even though dense plasma is generated at lateral portions 64 of two end portions 39 (two end portions in a direction perpendicular to the longitudinal direction X of the antenna; i.e. two end portions in the Z direction since the antenna 28 is disposed vertically in this embodiment) of each opening 37 of the high frequency electrode 30 and thin plasma is generated at lateral portions 65 of the center of each opening 37 near the outer side of the dielectric case 40, the density of the plasma is in the up-down direction with respect to the surface of the substrate in this embodiment, which is different from the conventional technology. Accordingly, while the plasma 50 diffuses toward the side of the substrate 2, the dense plasma and thin plasma are mixed to an extent to uniformize the density. Therefore, uniformity of the density of the plasma 50 near the substrate 2 is achieved easily.

(ii) Furthermore, because the antenna 28 is disposed in the direction that the main surface of the high frequency electrode 30 and the surface of the substrate 2 are substantially perpendicular to each other, when the potential of the high frequency electrode 30 is increased by applying the high frequency current I_{R} to the high frequency electrode 30, an equipotential surface 66 generated between the high frequency electrode 30 and the substrate 2 is curved in a valley shape under the high frequency electrode 30 when away from the substrate 2, as illustrated by FIG. 8. Accordingly, as the plasma 50 generated near the outer side of the dielectric case 40 diffuses toward the size of the substrate 2, the plasma 50 easily diffuses in the lateral direction, and from this aspect, the plasma density corresponding to the arrangement of the openings 37 of the high frequency electrode 30 is easily uniformized near the substrate 2.

Because of the aforementioned functions (i) and (ii), even without increasing the distance between the antenna 28 and the substrate 2, the plasma density corresponding to the arrangement of the openings 37 of the high frequency electrode 30 that constitutes the antenna 28 can be uniformized near the substrate 2 to improve the uniformity of substrate processing in the longitudinal direction X of the antenna 28. In the case of forming a film on the substrate 2, for example, the uniformity of the film thickness distribution in the longitudinal direction X of the antenna 28 can be enhanced.

Further, since it is not required to increase the distance between the antenna 28 and the substrate 2, increase of the sizes of the vacuum container 4 and the plasma processing apparatus can be avoided. Moreover, the time required for vacuum pumping of the vacuum chamber 4 can be shortened. In consideration of disposing the antenna 28 vertically and protruding of the antenna 28 toward the vacuum container 4, the increase in sizes of the vacuum container 4 and the plasma processing apparatus can be avoided.

### (2) Other Embodiments of the Plasma Processing Apparatus

The following mainly explains the differences between other embodiments and the above embodiment of the plasma processing apparatus of the present invention.

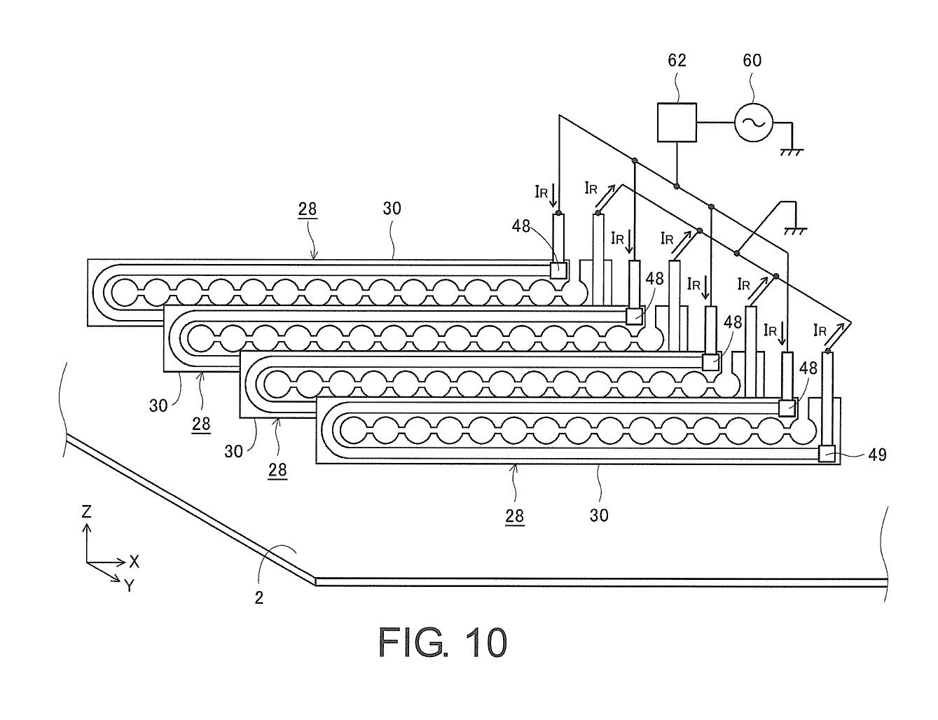

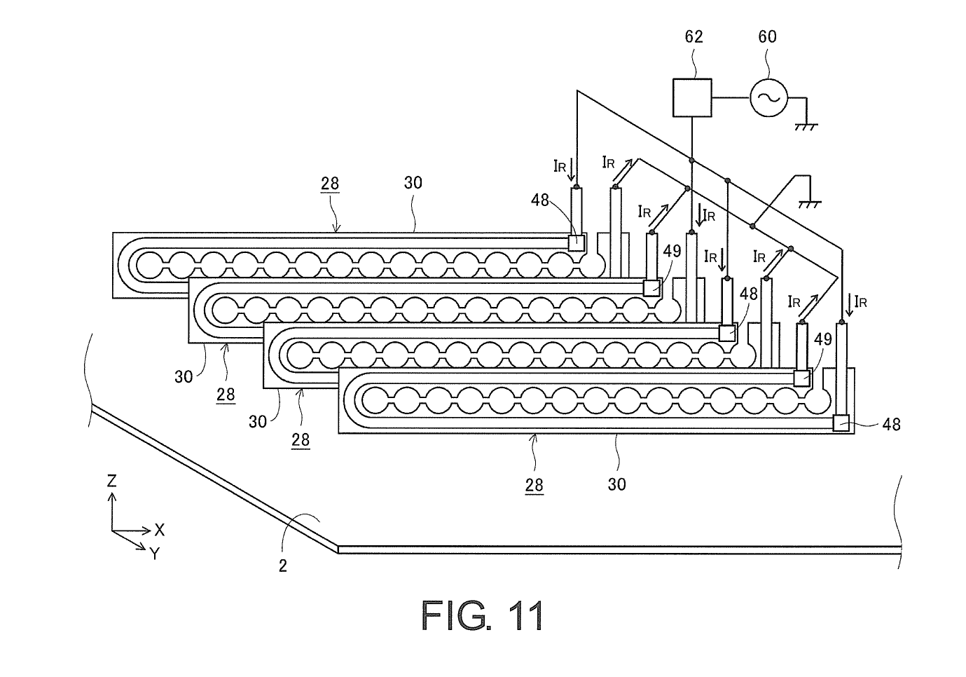

As illustrated by the embodiments of FIG. 10 and FIG. 11 respectively, a plurality of antennas 28, each having a substantially straight planar shape in the X direction, may be arranged in parallel to each other (more specifically, arranged side by side and in parallel to each other) along the surface of the substrate 2. By doing so, a plasma of larger area is generated for processing the substrate 2 of larger area. In this case, the high frequency power may be supplied in parallel to multiple antennas 28 from the common high frequency power supply 60, as shown in the figures, or the high frequency power may be separately supplied by different high frequency power supplies 60.

In the case of disposing multiple antennas 28 in parallel as illustrated by the embodiment of FIG. 10, the power feeding point 48 and the grounding point 49 of the high frequency electrode 30 that constitutes each antenna 28 may be respectively disposed on the same sides of the antennas 28 (i.e. in this embodiment, all the power feeding points 48 are disposed on the side opposite to the substrate 2, and all the grounding points 49 are disposed on the side of the substrate 2). In this case, as shown, it is preferable to dispose the grounding points 49 on the side of the substrate 2. By doing so, variation of the potential on the side of the grounding point 49 of the high frequency electrode 30 is smaller than that on the side of the power feeding point 48, and the electrode conductor with less potential variation is located on the side of the substrate 2. Thus, non-uniformity of the substrate processing resulting from the potential variation of the high frequency electrode 30 can be suppressed. When forming a film on the substrate 2, for example, the uniformity of the film thickness distribution can be improved.

In the case of disposing the multiple antennas 28 in parallel as illustrated by the embodiment of FIG. 11, the power feeding point 48 and the grounding point 49 of the high frequency electrode 30 that constitutes each antenna 28 may be alternately disposed on the antennas 28 (i.e. the power feeding points 48 and the grounding points 49 are alternately disposed on the side of the substrate 2). In this way, since the power feeding points 48 and the grounding points 49 of the high frequency electrodes 30 are disposed alternately, any imbalance that may occur in the plasma distribution in the longitudinal direction X of each antenna 28 due to the manner of arranging the power feeding points 48 and the grounding points 49 is offset easily. As a result, the uniformity of large-area plasma can be improved. Consequentially, when forming a film on the large-area substrate 2, for example, the uniformity of the film thickness distribution can be enhanced.

In the case of disposing multiple antennas 28 in parallel, all the antennas 28 may be equally spaced, or an interval of two end regions in the parallel direction Y of the antennas 28 may be smaller than an interval of the other regions. The plasma density of the two end regions in the parallel direction Y of the antennas usually tends to be lower than the plasma density of the other regions. Simply put, the reason is that, compared with the other regions where the plasma diffuses on both the left and the right sides, the plasma diffuses on only one side in the two end regions. Regarding this, by making the interval of the two end regions in the parallel direction Y of the antennas 28 smaller than the interval of the other regions as described above, the plasma density in the two end regions can be increased to compensate for the low plasma density, so as to improve the plasma uniformity in the parallel direction Y of the antennas 28. Thus, when forming a film on the large-area substrate 2, for example, the uniformity of the film thickness distribution can be enhanced.

Moreover, in the case of disposing multiple antennas 28 in parallel as described above, different from the embodiments of FIG. 10 and FIG. 11, locations of adjacent antennas 28 in the longitudinal direction X may be displaced for half of the pitch of the opening 37 to put the opening 37 and a connection portion 38 (see FIG. 6) between the openings 37 side by side in the Y direction for adjacent antennas 28.

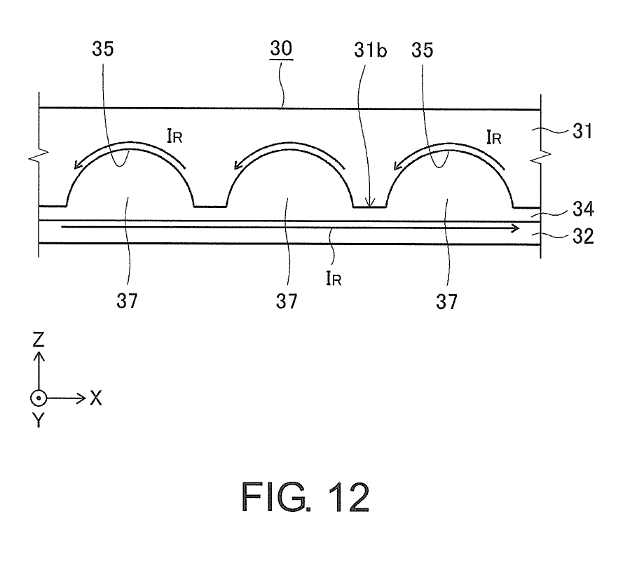

The high frequency electrode 30 that constitutes the antenna 28 may have the structure shown in FIG. 12, wherein the electrode conductor 31 of the high frequency electrode 30 is a rectangular plate while the electrode conductor 32 is a rod, and the two electrode conductors 31 and 32 are disposed close to and in parallel to each other with the gap 34 therebetween to form a rectangular plate shape as a whole, and the two electrode conductors 31 and 32 are connected by a conductor (omitted in the figure; see the conductor 33 of FIG. 6) at one end in the longitudinal direction to form a go-and-return conductor structure. The high frequency current I_{R} flows in opposite directions in the two electrode conductors 31 and 32. Moreover, cutouts 35 are formed on the edge 31b of the electrode conductor 31 having the rectangular plate shape on the side of the gap 34 to form multiple openings 37 arranged and dispersed along the longitudinal direction X of the high frequency electrode 30. In this embodiment, the antenna 28 is also disposed in the vacuum container 4 (see FIG. 4) in the direction that the main surface of the high frequency electrode 30 and the surface of the substrate 2 are substantially perpendicular to each other.

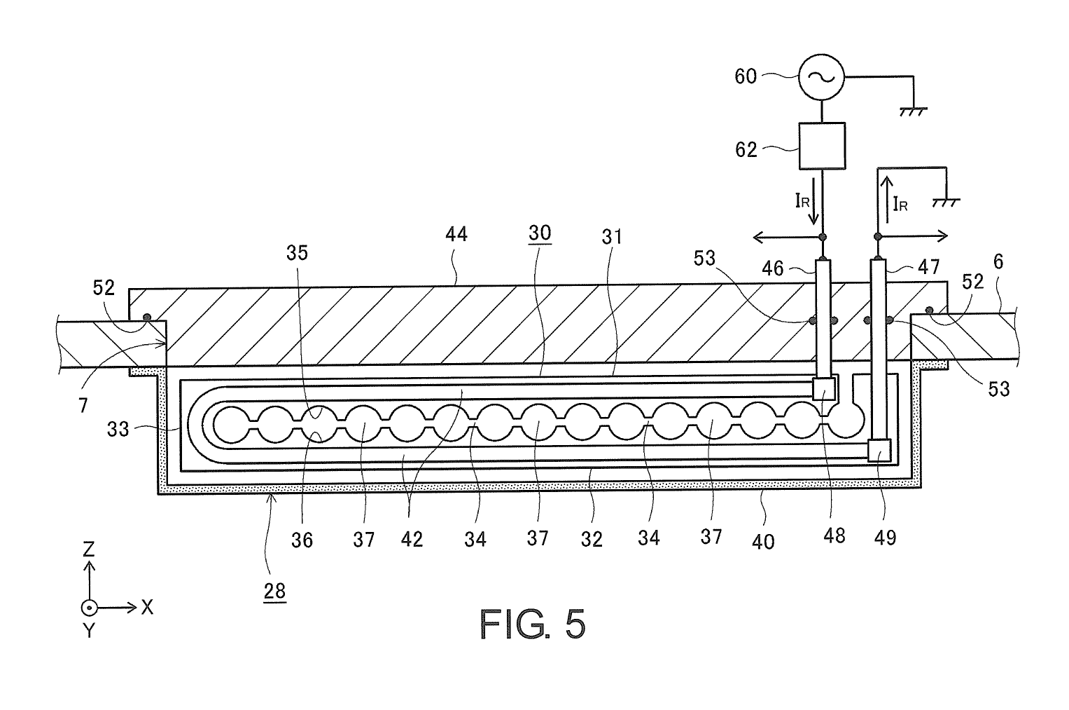

The same as the embodiments of FIG. 4 and FIG. 5, for example, the cooling pipe 42 may be disposed to serve as the cooling means of the high frequency electrode 30. Alternatively, on the side of the electrode conductor 32, the rod-shaped electrode conductor 32 may be formed hollow to be used as a cooling pipe.

In this embodiment, the opening 37 is semicircular, for example. Compared with the circular opening 37, the magnetic field generated near the semicircular opening 37 is weaker corresponding to the size of the semicircular opening 37. Except for this, this embodiment is almost the same as the above-described embodiments (see the descriptions of FIG. 4 to FIG. 6) and can achieve the same effects as the above embodiments.

In addition, since one of the two electrode conductors (i.e. the electrode conductor 32) that constitute the high frequency electrode 30 is rod-shaped, protrusion dimensions of the antenna 28 in the vacuum container 4 can be reduced, compared with the rectangular plate shape. As a result, the sizes of the vacuum container 4 and the plasma processing apparatus can be reduced. Moreover, the time required for vacuum pumping of the vacuum chamber 4 can be shortened.

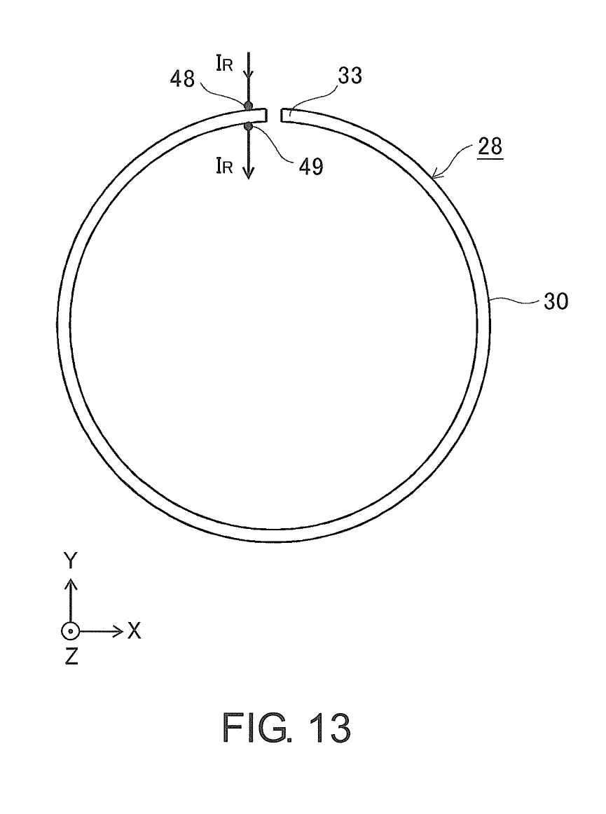

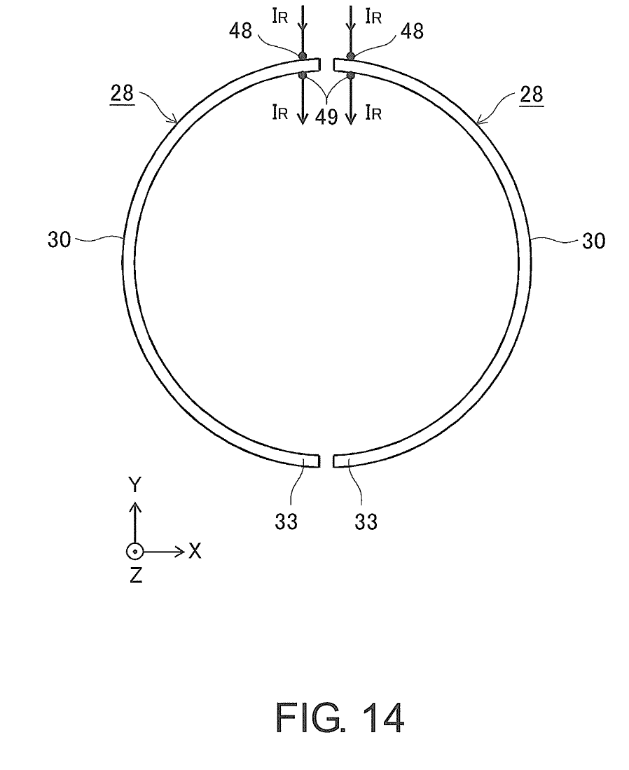

The planar shape of the antenna 28 may also be annular. FIG. 13 illustrates an embodiment where the antenna 28 is formed annular. The antenna 28 may be obtained by bending the antenna 28 of FIG. 5, for example, into an annular shape in a plane (i.e. the XY plane) parallel to the substrate 2. The dielectric case is omitted from FIG. 13. Because FIG. 13 is a plan view, FIG. 13 does not depict the gap 34, the openings 37, etc., of the high frequency electrode 30. However, in this embodiment, the high frequency electrode 30 also includes the electrode conductors 31 and 32, the gap 34, the openings 37, etc., as illustrated in FIG. 5, for example. The same applies to the embodiment illustrated by FIG. 14.

Multiple antennas 28 may be disposed to form an annular planar shape as a whole. FIG. 14 illustrates an embodiment where two antennas 28 are disposed to form an annular planar shape as a whole. Three or more antennas 28 may be disposed in the same way. The configuration of the power feeding points 48 and the grounding points 49 of the antennas 28 may be different from the embodiment illustrated by FIG. 14. For example, the conductor 33 for returning of one antenna 28 may be located adjacent to the power feeding point 48 and the grounding point 49 of one antenna 28.

In the above embodiment, because annular plasma is generated near the antenna 28 corresponding to the planar shape of the antenna 28, processing for a substrate or sputter target having a circular or nearly circular planar shape can be performed easily.

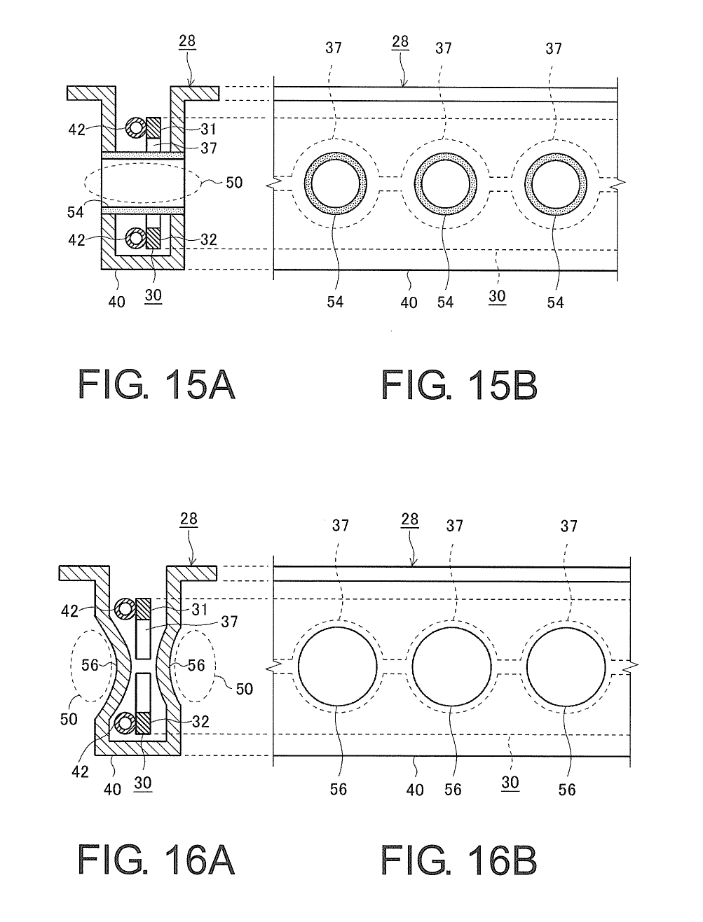

As illustrated by the embodiment of FIG. 15, a plurality of dielectric tubes 54, traversing the dielectric case 40, may be disposed to respectively pass through the openings 37 of the high frequency electrodes 30 in the dielectric case 40. The dielectric tubes 54 are glass tubes, quartz tubes, etc., for example.

As described above, because the openings 37 of the high frequency electrode 30 have the same function as coils, a strong magnetic field is generated near each opening 37. Since the dielectric tubes 54 pass through the openings 37, and like the vacuum container 4, the inside of the dielectric tubes 54 is vacuum and the gas 24 (see FIG. 4) is supplied thereto, dense plasma 50 can be generated in the dielectric tubes 54 using the strong magnetic field. As a result, the efficiency of plasma generation and utilization of the high frequency power can be improved.

At least one side surface of the dielectric case 40, i.e. a portion 56 facing each opening 37 of the high frequency electrode 30 in the dielectric case 40, may be partially recessed inward. In that case, preferably two side surfaces of the dielectric case 40 may be recessed as described above, as illustrated in FIG. 16.

As described above, a strong magnetic field is generated near each opening 37 of the high frequency electrode 30 that constitutes the antenna 28, and the side surfaces of the portions 56 of the dielectric case 40, which correspond to the openings 37, are recessed inward to be closer to the openings 37. Thus, dense plasma 50 can be generated near the recessed portions 56 using the strong magnetic field. As a result, the efficiency of plasma generation and utilization of the high frequency power can be improved.

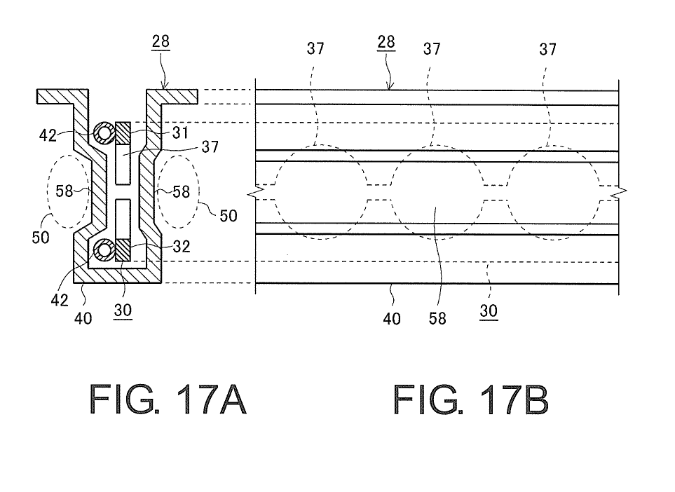

At least one side surface of the dielectric case 40, i.e. a region 58 including the portion facing the openings 37 of the high frequency electrode 30 in the dielectric case 40, may be recessed inward continuously along the longitudinal direction X of the antenna 28. In that case, preferably two side surfaces of the dielectric case 40 may be recessed as described above, as illustrated in FIG. 17.

As described above, a strong magnetic field is generated near each opening 37 of the high frequency electrode 30 that constitutes the antenna 28, and the side surface of the region 58 of the dielectric case 40, which includes the portion corresponding to the openings 37, is recessed inward to be closer to the openings 37. Thus, dense plasma 50 can be generated near the recessed region 58 using the strong magnetic field. As a result, the efficiency of plasma generation and utilization of the high frequency power can be improved.

### (3) Yet Another Embodiment of the Plasma Processing Apparatus

As illustrated by the embodiment of FIG. 4, if the cooling pipe 42 is attached to one main surface of the high frequency electrode 30 that constitutes the antenna 28, and distances L₃ and L₄ respectively between the main surfaces of the high frequency electrode 30 on the left and right sides (i.e. two sides in the Y direction perpendicular to the longitudinal direction X; the same hereinafter) and external surfaces (i.e. external surfaces of the side surfaces) of the dielectric case 40 opposite thereto are different from each other (L₃>L₄ according to the embodiment shown), more specifically, the density of the plasma 50 generated by using the antenna 28 may differ on the left and right sides of the antenna 28. The reason is that the shorter distance, e.g. the distance L₃ or the distance L₄, causes denser plasma 50 due to a stronger magnetic field foamed at a location closer to the high frequency electrode 30. That is to say, in the case of the antenna 28 shown in FIG. 4, the plasma 50 generated on the right side of the antenna 28 may be denser than the plasma 50 generated on the left side.

If there is a difference in plasma density between the left and the right sides of the antenna 28, the discrepant plasma density may result in reduction of the uniformity of substrate processing in the left-right direction (i.e. the Y direction).

In this situation, it may be considered to increase the distance between the antenna 28 and the substrate 2 (see the distance L₂ in FIG. 8) to increase diffusion of the plasma 50 in the Y direction before the plasma 50 reaches the substrate 2, so as to uniformize the plasma density near the substrate 2 and improve the uniformity of substrate processing. However, as mentioned above, the increase of the distance between the antenna 28 and the substrate 2 may cause other problems, i.e. increase of the size of the plasma processing apparatus.

In addition, the high frequency electrode 30 with the cooling pipe 42 attached to one surface thereof may be arranged to make the distances L₃ and L₄ substantially equal to each other in the dielectric case 40. In this way, the difference in plasma density between the left and right sides of the antenna 28 may be reduced. However, the structures (the high frequency electrode 30 and the cooling pipe 42) in the dielectric case 40 are still asymmetrical on the left and right sides, and from the electromagnetic aspect and the aspect of cooling efficiency of the high frequency electrode 30, there is room for improvement.

Embodiments of the plasma processing apparatus for further improving the aforementioned problems are described hereinafter. The paragraphs below mainly explain the differences between the following embodiments and the above embodiment.

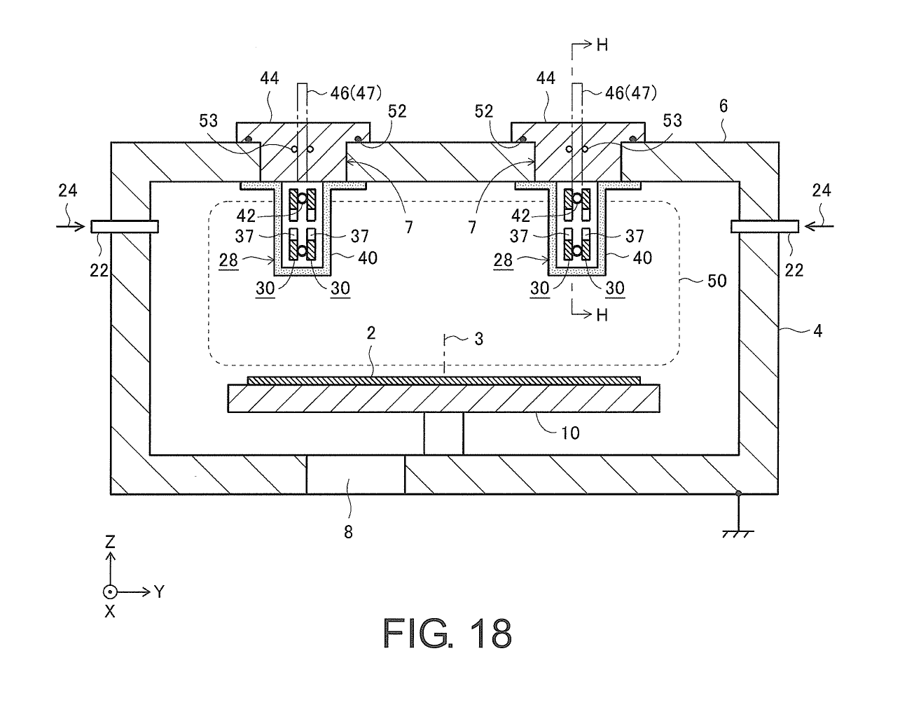

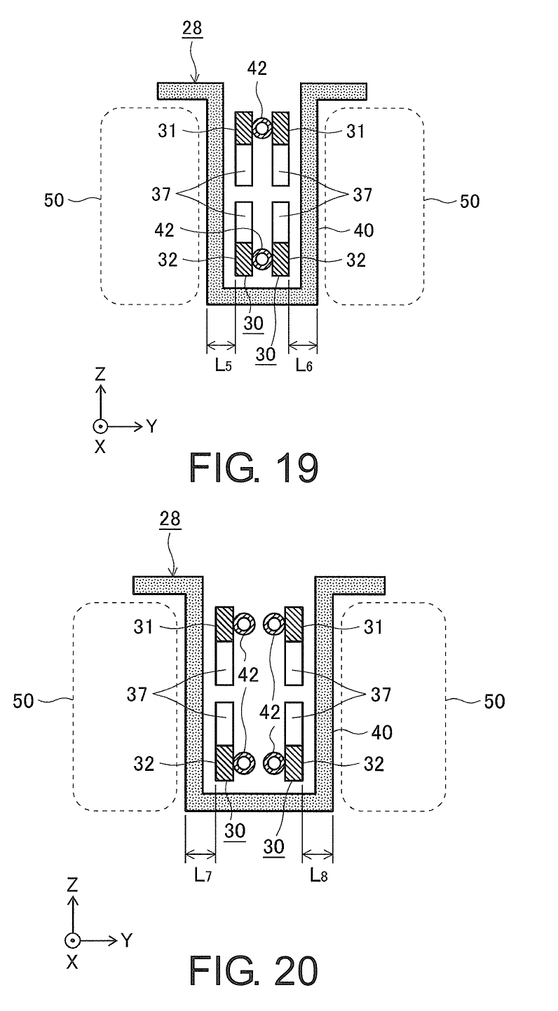

In the embodiment shown in FIG. 18 and FIG. 19, each antenna 28 includes two high frequency electrodes 30 that have the same structure, and each antenna 28 is formed with a structure for receiving the cooling pipe 42 in the dielectric case 40, wherein the cooling pipe 42 is held between the two high frequency electrodes 30, and a coolant (e.g. cooling water) is supplied to flow in the cooling pipe 42 for cooling the two high frequency electrodes 30. The two high frequency electrodes 30 are disposed substantially in parallel to each other.

Moreover, the antenna 28 is disposed in the vacuum container 4 in the direction that the main surface of the high frequency electrode 30 constituting each antenna 28 and the surface of the substrate 2 are substantially perpendicular to each other.

A view taken along the direction of the arrow H-H in FIG. 18 is the same as FIG. 5 and FIG. 6 and thus is not repeated hereinafter. Reference will be made to FIG. 5 and FIG. 6. The antenna 28 shown in FIG. 18 has one more high frequency electrode 30, which overlaps the other high frequency electrode 30 from the upper side of the paper surface of FIG. 5.

The cooling pipe 42 has a portion that extends in the longitudinal direction X of the two high frequency electrodes 30 and avoids the openings 37 of the two high frequency electrodes 30 (see FIG. 5). The cooling pipe 42 is attached to the two high frequency electrodes 30 (from another perspective, the two high frequency electrodes 30 are attached to two sides of the cooling pipe 42) by a bonding means, such as soldering.

The high frequency power provided by the high frequency power supply 60 (see FIG. 5 and FIG. 6) is supplied in parallel to the two high frequency electrodes 30 constituting each antenna 28 through the feedthroughs 46 and 47. That is, in this embodiment, the feedthroughs 46 and 47 are common for the two high frequency electrodes 30. Moreover, the coolant is supplied to the cooling pipe 42 through the feedthroughs 46 and 47. In other words, the feedthroughs 46 and 47 are used for both supplying the high frequency power and the coolant.

The number of the antennas 28, the structure of each high frequency electrode 30 that constitutes each antenna 28, the dielectric case 40, the manner of supplying the high frequency power from the high frequency power supply 60 to each antenna 28, the function of generating the plasma 50 by applying the high frequency current I_{R} to each high frequency electrode 30 (more specifically, the electrode conductors 31 and 32 that constitute the high frequency electrode 30) of each antenna 28, etc., are basically the same as those of the embodiments described with reference to FIG. 4 to FIG. 6. Thus, the descriptions are not repeated hereinafter.

Preferably, the openings 37 of the two high frequency electrodes 30 (in other words, the left and the right high frequency electrodes 30) are disposed at locations opposite to each other. Such an arrangement is adopted in this embodiment. The same applies to the other embodiments which will be described later.

Further, with reference to FIG. 19, in each antenna 28, distances L₅ and L₆ respectively between the outer main surfaces of each of the two high frequency electrodes 30 and the external surfaces of the dielectric case 40 opposite thereto (i.e. external surfaces of the side surfaces; the same hereinafter) are made substantially equal to each other for the two high frequency electrodes 30 (that is, L₅=L₆ or L₅≈L₆).

The plasma processing apparatus of this embodiment also has the structure that the high frequency electrode 30 constituting each antenna 28 forms a go-and-return conductor structure when viewed as a whole and multiple openings 37 are dispersed and arranged in the longitudinal direction X on each high frequency electrode 30. Therefore, the plasma processing apparatus achieves the same effects as the plasma processing apparatus of the embodiments illustrated in FIG. 4 to FIG. 6 above.

Furthermore, in the plasma processing apparatus of this embodiment, the antenna 28 is also disposed in the vacuum container 4 in the direction that the main surface of the high frequency electrode 30 and the surface of the substrate 2 are substantially perpendicular to each other. Thus, for the same reasons as described in the embodiment of FIG. 4 to FIG. 6 above, even without increasing the distance between the antenna 28 and the substrate 2, the plasma density corresponding to the arrangement of the openings 37 of the high frequency electrode 30 that constitutes the antenna 28 can be uniformized near the substrate 2 to improve the uniformity of substrate processing in the longitudinal direction X of the antenna 28.

As a result, even though the distance between the antenna 28 and the substrate 2 is not increased, the plasma density corresponding to the arrangement of the openings 37 of the high frequency electrode 30 that constitutes the antenna 28 can be uniformized near the substrate 2, and the uniformity of substrate processing in the longitudinal direction X of the antenna 28 can be improved. In addition, since it is not required to increase the distance between the antenna 28 and the substrate 2, increase of the sizes of the vacuum container 4 and the plasma processing apparatus can be avoided.

Furthermore, the antenna 28 includes two high frequency electrodes 30 respectively having the aforementioned structure and has the structure that receives the cooling pipe 42, held between the two high frequency electrodes 30, in the dielectric case 40. Moreover, the distances L₅ and L₆ respectively between the outer main surfaces of the high frequency electrodes 30 and the external surfaces of the dielectric case 40 opposite thereto are made substantially equal to each other for the two high frequency electrodes 30. Therefore, the density of the plasma 50 generated by using the antenna 28 can be uniformized on the left and right sides of the antenna 28. Since the distances L₅ and L₆ are substantially equal to each other, the intensity of the magnetic fields generated by the two high frequency electrodes 30 are also substantially equal to each other near the side surfaces of the dielectric case 40 on the left and right sides. Accordingly, the density of the plasma 50 generated near the side surfaces of the dielectric case 40 on the left and right sides becomes substantially equal.

As a result, the uniformity of substrate processing in the left-right direction Y of the antenna 28 can be enhanced as well. Further, since it is not required to increase the distance between the antenna 28 and the substrate 2 for enhancing the uniformity of the plasma density by plasma diffusion, increase of the sizes of the vacuum container 4 and the plasma processing apparatus can be avoided.

In other words, according to this embodiment, the uniformity of substrate processing in the longitudinal direction X of the antenna 28 can be improved as described above, and the uniformity of substrate processing in the left-right direction Y of the antenna 28 can be improved as well. By combining the two effects, the uniformity of the processing in two dimensions of the substrate surface can be improved even without increasing the distance between the antenna 28 and the substrate 2.

In addition, the left-right symmetry of the structures (the high frequency electrodes 30 and the cooling pipe 42 in this embodiment) in the dielectric case 40 is also favorable. The same applies to other embodiments of the antenna 28 which will be described later.

Next, another embodiment of the antenna 28 is described below, wherein parts identical to or equivalent to those of FIG. 18 and FIG. 19 are represented by the same reference numerals, and the following paragraphs mainly explain the differences between this embodiment and the embodiments of FIG. 18 and FIG. 19.

In the embodiment of FIG. 20, the antenna 28 includes two high frequency electrodes 30 respectively having the aforementioned structure, and the antenna 28 is formed with a structure that a cooling pipe 42 having the aforementioned structure is respectively attached to one main surface of each high frequency electrode 30, and the two high frequency electrodes 30 are received in the dielectric case 40 in a direction that the cooling pipes 42 are located on the inner sides. The two high frequency electrodes 30 are disposed substantially in parallel to each other. Each of the cooling pipes 42 has a portion that extends in the longitudinal direction X of the high frequency electrode 30 and avoids the openings 37 of the high frequency electrode 30 to which the cooling pipe 42 is attached (see FIG. 5).

Furthermore, distances L₇ and L₈ respectively between the outer main surfaces of the high frequency electrodes 30 and the external surfaces of the dielectric case 40 opposite thereto are made substantially equal to each other for the two high frequency electrodes 30 (that is, L₇=L₈ or L₇≈L₈).

The high frequency power provided by the high frequency power supply 60 is supplied in parallel to the two high frequency electrodes 30 constituting the antenna 28 using and through two sets of the aforementioned feedthroughs 46 and 47, for example. The supply of the high frequency power to the electrode conductors 31 and 32 that constitute each high frequency electrode 30 is the same as the above described embodiments. A coolant is supplied to the two cooling pipes 42 using the two sets of feedthroughs 46 and 47.

The plasma processing apparatus that includes the antenna 28 of this embodiment also has the structure that the antenna 28 is arranged in the direction that the main surfaces of the high frequency electrodes 30 and the surface of the substrate 2 (see FIG. 18) are substantially perpendicular to each other. Therefore, the plasma processing apparatus achieves the same effects as the plasma processing apparatus of the embodiment of FIG. 18 and FIG. 19. The same also applies to other embodiments of the antenna 28, which will be described later.

Moreover, because the distances L₇ and L₈ between the outer main surfaces of the high frequency electrodes 30 and the external surfaces of the dielectric case 40 opposite thereto are substantially equal to each other as described above, the same as the above embodiments, the density of the plasma 50 generated using the antenna 28 can be uniformized on the left and right sides of the antenna 28.

As a result, the uniformity of substrate processing in the left-right direction Y of the antenna 28 can be enhanced as well. Further, since it is not required to increase the distance between the antenna 28 and the substrate 2 for enhancing the uniformity of the plasma density by plasma diffusion, increase of the sizes of the vacuum container 4 and the plasma processing apparatus can be avoided.

In other words, when the plasma processing apparatus provided with the antenna 28 is used, the uniformity of substrate processing in the longitudinal direction X of the antenna 28 can be improved as described above, and the uniformity of substrate processing in the left-right direction Y of the antenna 28 can be improved as well. By combining the two effects, the uniformity of the processing in two dimensions of the substrate surface can be enhanced even without increasing the distance between the antenna 28 and the substrate 2.

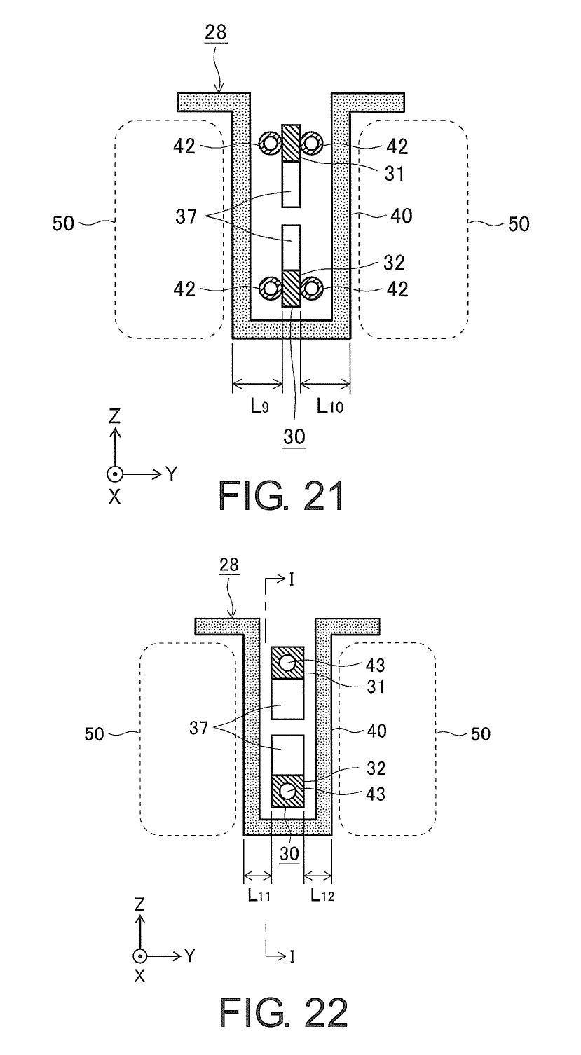

The antenna 28 in the embodiment of FIG. 21 has the structure that the cooling pipes 42 having the aforementioned structure are respectively attached to two main surfaces of the high frequency electrode 30 having the aforementioned structure. The cooling pipes 42 disposed on the two main surfaces respectively have a portion that extends in the longitudinal direction X of the high frequency electrode 30 and avoids the openings 37 of the high frequency electrode 30 (see FIG. 5). It is preferable that the diameters of the cooling pipes 42 on the two main surfaces are substantially equal. In this way, the symmetry of the structures on the left and right sides in the dielectric case 40 is improved.

In addition, distances L₉ and L₁₀ respectively between the two main surfaces of the high frequency electrode 30 and the external surfaces of the dielectric case 40 opposite thereto are substantially equal to each other (that is, L₉=L₁₀ or L₉≈L₁₀).

The high frequency power provided by the high frequency power supply 60 is supplied in parallel to the two main surfaces of the high frequency electrode 30 by using two sets of the feedthroughs 46 and 47, for example. Nevertheless, since the high frequency electrode 30 is generally thin, the high frequency power may be supplied to only one main surface. The supply of the high frequency power to the electrode conductors 31 and 32 that constitute the high frequency electrode 30 is the same as the above described embodiments. A coolant is supplied to the two cooling pipes 42 using the two sets of feedthroughs 46 and 47.

In the case of this embodiment, since the distances L₉ and L₁₀ between the outer main surfaces of the high frequency electrode 30 and the external surfaces of the dielectric case 40 opposite thereto are substantially equal to each other as described above, the same as the above described embodiments, the density of the plasma 50 generated using the antenna 28 can be uniformized on the left and right sides of the antenna 28.

Furthermore, although a portion of the high frequency current may flow to the cooling pipes 42 on two main surfaces of the high frequency electrode 30 and contribute to generation of the high frequency magnetic field and generation of the plasma 50, since the distances between the cooling pipes 42 on the main surfaces on the left and right sides of the high frequency electrode 30 and the dielectric case 40 opposite thereto are substantially equal, it also contributes to uniformizing the density of the plasma 50 generated using the antenna 28 on the left and right sides of the antenna 28.

As a result, the uniformity of substrate processing in the left-right direction Y of the antenna 28 can be enhanced as well. Further, since it is not required to increase the distance between the antenna 28 and the substrate 2 for enhancing the uniformity of the plasma density by plasma diffusion, increase of the sizes of the vacuum container 4 and the plasma processing apparatus can be avoided.

In other words, when the plasma processing apparatus provided with the antenna 28 is used, the uniformity of substrate processing in the longitudinal direction X of the antenna 28 can be improved as described above, and the uniformity of substrate processing in the left-right direction Y of the antenna 28 can be improved as well. By combining the two effects, the uniformity of the processing in two dimensions of the substrate surface can be enhanced even without increasing the distance between the antenna 28 and the substrate 2.

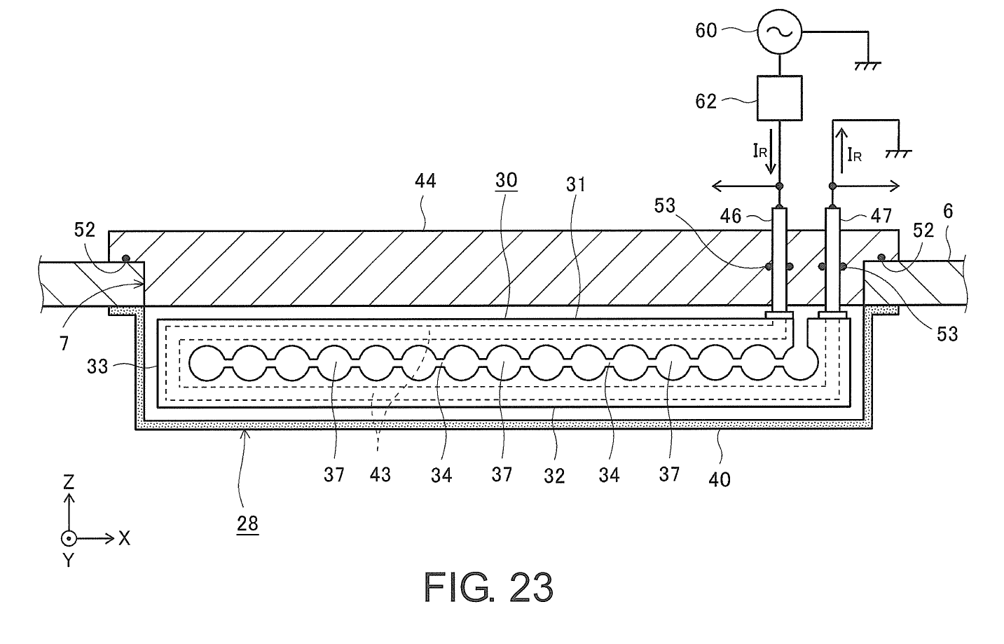

The antenna 28 in the embodiment of FIG. 22 has a structure that a coolant passage 43, in which a coolant flows for cooling the high frequency electrode 30, is disposed in the high frequency electrode 30 having the aforementioned structure. The coolant passage 43 has a portion that extends in the longitudinal direction X of the high frequency electrode 30 and avoids the openings 37 of the high frequency electrode 30 (see FIG. 23).

In addition, distances L₁₁ and L₁₂ respectively between the two main surfaces of the high frequency electrode 30 and the external surfaces of the dielectric case 40 opposite thereto are substantially equal to each other (that is, L₁₁=L₁₂ or L₁₁≈L₁₂).

Supply of the high frequency power from the high frequency power supply 60 to the high frequency electrode 30 that constitutes the antenna 28 and supply of the coolant to the coolant passage 43 in the high frequency electrode 30 are carried out through the feedthroughs 46 and 47. The supply of the high frequency power to the electrode conductors 31 and 32 that constitute the high frequency electrode 30 is the same as the above described embodiments.

In the case of this embodiment, because the distances L₁₁ and L₁₂ respectively between the outer main surfaces of the high frequency electrode 30 and the external surfaces of the dielectric case 40 opposite thereto are substantially equal to each other as described above, the same as the above described embodiments, the density of the plasma 50 generated using the antenna 28 can be uniformized on the left and right sides of the antenna 28.

As a result, the uniformity of substrate processing in the left-right direction Y of the antenna 28 can be enhanced as well. Further, since it is not required to increase the distance between the antenna 28 and the substrate 2 for enhancing the uniformity of the plasma density by plasma diffusion, increase of the sizes of the vacuum container 4 and the plasma processing apparatus can be avoided.

In other words, when the plasma processing apparatus provided with the antenna 28 is used, the uniformity of substrate processing in the longitudinal direction X of the antenna 28 can be improved as described above, and the uniformity of substrate processing in the left-right direction Y of the antenna 28 can be improved as well. By combining the two effects, the uniformity of the processing in two dimensions of the substrate surface can be enhanced even without increasing the distance between the antenna 28 and the substrate 2.

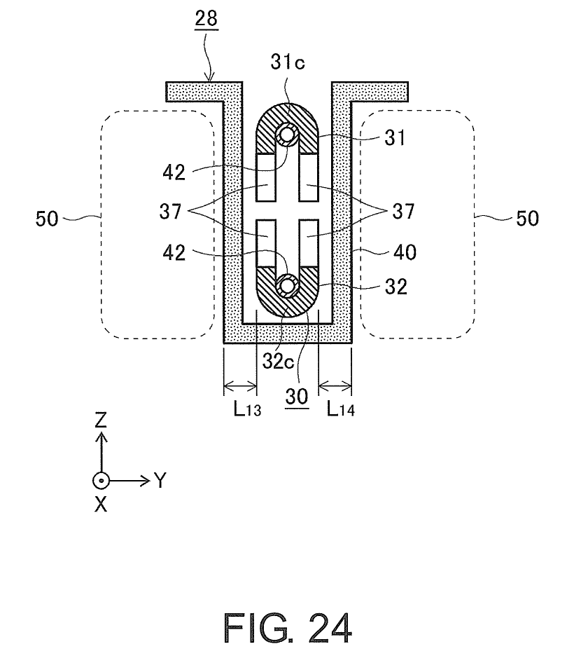

The antenna 28 of the embodiment shown in FIG. 24 is, so to speak, obtained by modifying the embodiment of FIG. 19 and includes a pair of upper and lower electrode conductors 31 and 32, respectively bent to form a U-shaped cross-section, to serve as the two electrode conductors constituting the high frequency electrode 30. Two edges of a bent portion 31c of the electrode conductor 31 and two edges of a bent portion 32c of the other electrode conductor 32 are disposed opposite to each other with a gap (see the gap 34 of FIG. 5, for example) therebetween. The bent portions 31c and 32c are bent round. According to the present application, the structure of such a high frequency electrode 30 is also included in the scope of the structure that two electrode conductors 31 and 32 are disposed close to and in parallel to each other with a gap therebetween to form a rectangular plate shape as a whole.

The high frequency electrode 30 also has a go-and-return conductor structure formed by connecting the two electrode conductors 31 and 32 with a conductor at one side in the longitudinal direction X, and the high frequency current I_{R} flows in opposite directions in the two electrode conductors 31 and 32. Moreover, cutouts (see the cutouts 35 and 36 of FIG. 5, for example) are respectively formed on opposite edges of the two electrode conductors 31 and 32 to face each other across the gap. The opposite cutouts respectively form a plurality of openings 37 that are arranged and dispersed along the longitudinal direction X of the high frequency electrode 30. Preferably, the openings 37 on the left and right sides of the high frequency electrode 30 are disposed at locations opposite to each other. Such an arrangement is adopted in this embodiment.

Further, the antenna 28 has the structure that receives the cooling pipe 42 in the dielectric case 40, wherein the cooling pipe 42, in which the coolant flows, is respectively held between the electrode conductors 31 and 32 that are bent to form the U-shaped cross-section for cooling the high frequency electrode 30. The cooling pipe 42 has a portion that extends in the longitudinal direction X of the high frequency electrode 30 and avoids the openings 37 of the high frequency electrode 30 (see the cooling pipe 42 of FIG. 5). The cooling pipe 42 is attached to the electrode conductors 31 and 32 by a bonding means, such as soldering, for example.

In addition, distances L₁₃ and L₁₄ respectively between two outer main surfaces of the high frequency electrode 30 and the external surfaces of the dielectric case 40 opposite thereto are substantially equal to each other (that is, L₁₃=L₁₄ or L₁₃≈L₁₄).

The high frequency power provided by the high frequency power supply 60 is supplied to the high frequency electrode 30 constituting the antenna 28 through the feedthroughs 46 and 47, for example. The coolant is supplied to the cooling pipe 42 using the feedthroughs 46 and 47.

In the case of this embodiment, because the distances L₁₃ and L₁₄ between the two outer main surfaces of the high frequency electrode 30 and the external surfaces of the dielectric case 40 opposite thereto are substantially equal to each other as described above, the same as the above described embodiments, the density of the plasma 50 generated using the antenna 28 can be uniformized on the left and right sides of the antenna 28.

As a result, the uniformity of substrate processing in the left-right direction Y of the antenna 28 can be enhanced as well. Further, since it is not required to increase the distance between the antenna 28 and the substrate 2 for enhancing the uniformity of the plasma density by plasma diffusion, increase of the sizes of the vacuum container 4 and the plasma processing apparatus can be avoided.

In other words, when the plasma processing apparatus provided with the antenna 28 is used, the uniformity of substrate processing in the longitudinal direction X of the antenna 28 can be improved as described above, and the uniformity of substrate processing in the left-right direction Y of the antenna 28 can be improved as well. By combining the two effects, the uniformity of the processing in two dimensions of the substrate surface can be enhanced even without increasing the distance between the antenna 28 and the substrate 2.

Besides, because the two electrode conductors 31 and 32 that constitute the high frequency electrode 30 are bent as described above, at least an angular portion of the bent portions 31c and 32c is eliminated. Reduction of the angular portion can reduce electric field concentration around the high frequency electrode 30 during application of the high frequency power. As a result, abnormal electrical discharge can be suppressed.

The cooling pipe 42 is disposed to inner surface portions of the bent portions 31c and 32c of the electrode conductors 31 and 32 as described in this embodiment. The cooling pipe 42 may be attached to the inner surface portions to achieve heat transfer with the inner surface portions or may be separated from the inner surface portions of the bent portions 31c and 32c. In the case where the cooling pipe 42 is attached to the inner surface portions of the bent portions 31c and 32c, for example, inner surfaces of the bent portions 31c and 32c are formed with a bend radius corresponding to an outer diameter of the cooling pipe 42, and the cooling pipe 42 may be attached to the inner surface portions by a bonding means, such as soldering, for example.

If the cooling pipe 42 is attached to the inner surface portions of the bent portions 31c and 32c as described above, heat transfer area between the cooling pipe 42 and the electrode conductors 31 and 32 is increased. Thus, the cooling capability of the high frequency electrode 30 is improved.

In comparison with the case where the cooling pipe 42 is attached and held between two plate-shaped high frequency electrodes 30 as illustrated in the embodiment of FIG. 19 for example, this embodiment where the cooling pipe 42 is attached to the inner surface portions of the bent portions 31c and 32c of the bent electrode conductors 31 and 32 as illustrated by FIG. 24 improves the workability of the process of bonding (e.g. soldering) the cooling pipe 42 to the electrode conductors 31 and 32 and thus reduces the processing costs in terms of work time and work assistance jigs.

The antenna 28 of the above embodiments does not necessarily have the straight planar shape, and the planar shape of the antenna 28 may be other shapes, such as curved and annular, for example.

### (4) An Embodiment Where Multiple Antennas are Arranged in Parallel

In the case where a plurality of the aforementioned antennas 28, each having the substantially straight planar shape, are arranged in parallel to each other along the surface of the substrate 2, specifically, if an impedance difference caused by a difference of temperature rise of the high frequency electrode 30 constituting each antenna 28 results in an impedance difference of a high frequency power supply circuit to each antenna 28, for example, the uniformity of the intensity of the magnetic field generated by each antenna 28 may decrease and the plasma uniformity in the parallel direction of the antennas 28 may decrease. An embodiment of the plasma processing apparatus for further improving the aforementioned problems is described hereinafter. The following paragraphs mainly explain the differences between the present embodiment and the above embodiments.

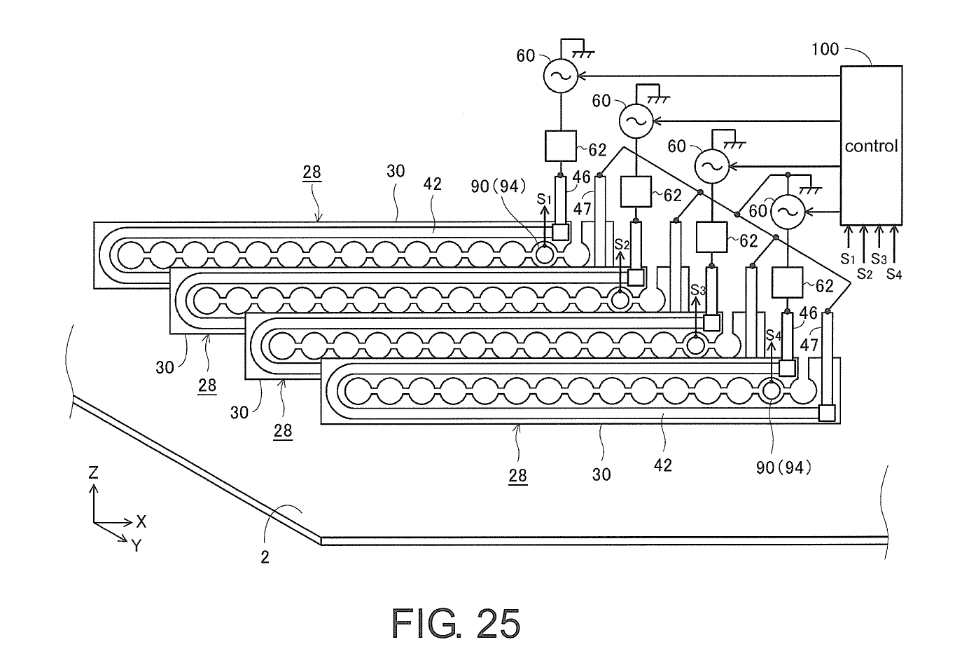

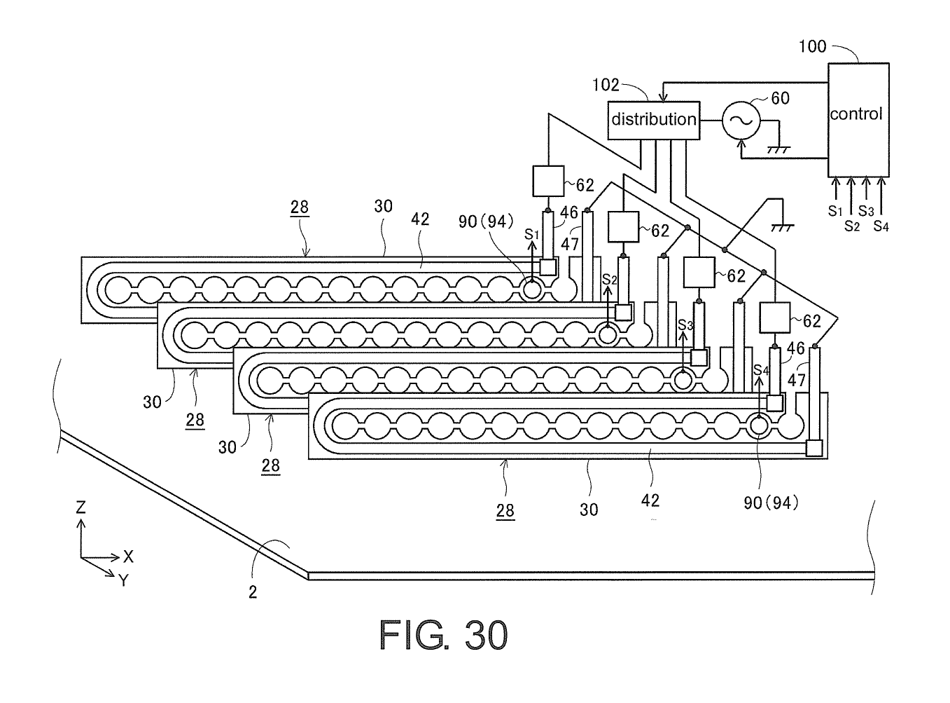

In the plasma processing apparatus of the embodiment shown in FIG. 25, a plurality of the antennas 28 each having the substantially straight planar shape in the X direction are arranged in the Y direction to be side by side along the surface of the substrate 2 (more specifically, arranged in parallel to each other). By doing so, a plasma of a larger area is generated and can be used for processing a substrate 2 having a larger area. Four antennas 28 are depicted in FIG. 25 in order to simplify the illustration. However, the number of the antennas 28 is not limited thereto. The same also applies to the embodiment of FIG. 30 which will be described later.

In the embodiment shown in FIG. 25, each antenna 28 has the structure that receives the cooling pipe 42 attached to one main surface of the high frequency electrode 30 in the dielectric case 40, which is the same as the embodiment of FIG. 4. However, the antenna 28 may also have the structures illustrated in FIG. 18 to FIG. 24. Supply of the high frequency power to the high frequency electrode 30 of each antenna 28 and supply of the coolant to each cooling pipe 42 are carried out through the feedthroughs 46 and 47. The above also applies to the embodiment of FIG. 30 which will be described later.

In any case, each antenna 28 is disposed in the direction that the main surface of the high frequency electrode 30 and the surface of the substrate 2 are substantially perpendicular to each other in the situation of this embodiment. Thus, with use of such an arrangement, the aforementioned effects can be achieved.

Furthermore, the plasma processing apparatus of FIG. 25 includes a plurality of high frequency power supplies 60 that respectively supply the high frequency power to the antennas 28, a plurality of magnetic field sensors 90 that are respectively disposed at substantially the same location with respect to the antennas 28 and detect the intensity of the magnetic field generated by each antenna 28, and a control device 100 that controls the high frequency power outputted by the high frequency power supplies 60 responsive to outputs of the magnetic field sensors 90 such that the outputs are substantially equal to each other.

A matching circuit 62 may be respectively provided between each high frequency power supply 60 and the corresponding antenna 28 as required.

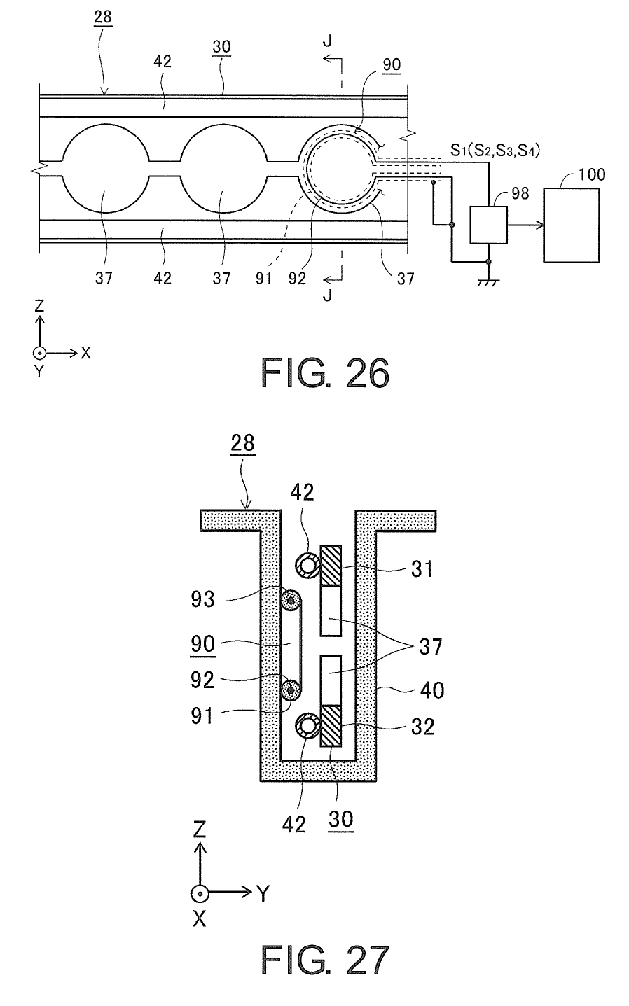

Each magnetic field sensor 90 (and each electric field sensor 94 which will be described later) is illustrated in a simplified form in FIG. 25. The same also applies to the below-described FIG. 30. A more specific embodiment of the magnetic field sensor 90 is explained below with reference to FIG. 26 and FIG. 27. In FIG. 26, in order to illustrate a core wire 92 as the main element, a dielectric 93 is omitted and a conductor tube 91 is represented by broken lines. Details of the above are illustrated in FIG. 27.

Each magnetic field sensor 90 has a structure that the core wire (conductive wire) 92 is disposed to pass through a central axis of the conductor tube 91 that has a generally loop shape, and the dielectric 93 is filled between the core wire 92 and the conductor tube 91 for electrical insulation. The conductor tube 91 is open at one point and electrically grounded at one point, so as not to form a closed circuit. The core wire 92 also has a generally loop shape, and an output S₁ (or S₂, S₃, or S₄) is obtained from two ends of the core wire 92. Although the conductor tube 91 may not be a necessary element, it is preferable to dispose the conductor tube 91. By doing so, the electric field is shielded by the conductor tube 91 to prevent the core wire 92 from influence of the electric field.

The magnetic field sensor 90 is disposed to be substantially parallel to the main surface of the high frequency electrode 30 near the high frequency electrode 30 (more specifically, a circular surface of the core wire 92 is substantially parallel to the main surface of the high frequency electrode 30). With such an arrangement, the output of the magnetic field sensor 90 is increased. In this arrangement, the magnetic field sensor 90 may be disposed at any location with respect to the high frequency electrode 30. However, since the magnetic field is strong near the opening 37 of the high frequency electrode 30 as described above, it is preferable to dispose the magnetic field sensor 90 at a location opposite to the opening 37, and it is more preferable to dispose the magnetic field sensor 90 coaxially with the center of the opening 37. In this way, the output of the magnetic field sensor 90 is further increased. However, in any case, the magnetic field sensors 90 are respectively disposed at substantially the same locations and in the same states with respect to the antennas 28 (more specifically, the high frequency electrodes 30). Accordingly, the conditions for detection of the magnetic fields performed by the magnetic field sensors 90 can be uniformized.

As illustrated by the embodiment of FIG. 27, for example, the magnetic field sensors 90 may also be attached to internal surfaces of the dielectric case 40.

When supplying the high frequency power to each antenna 28 (more specifically, the high frequency electrode 30) to cause the high frequency current I_{R} to flow as described above, a high frequency magnetic field is generated around each high frequency electrode 30 to interlink each magnetic field sensor 90 (more specifically, the core wire 92 thereof), and due to electromagnetic induction, a high frequency voltage corresponding to a time variation of magnetic flux linkage is induced in each core wire 92 and outputted as the output S₁ (or S₂, S₃, or S₄). The outputs S₁-S₄ may be supplied to the control device 100 directly, or a signal converter 98 may be disposed in the way for converting the outputs S₁-S₄ into signals that can be easily processed by the control device 100 (e.g. direct current or direct voltage) to be supplied to the control device 100.

The control device 100 controls the high frequency power outputted by the high frequency power supply 60 to make the outputs S₁-S₄ of the magnetic field sensors 90 (or the signals converted therefrom; the same hereinafter) substantially equal. For example, if the output of one magnetic field sensor 90 is smaller than the others, the high frequency power supplied to the antenna 28 to which this magnetic field sensor 90 is disposed is increased to make the output of this magnetic field sensor 90 equal to the other outputs, and vice versa.

For example, even if an impedance difference caused by the difference in temperature rise of the high frequency electrode 30 constituting each antenna 28 results in an impedance difference of a high frequency power supply circuit to each antenna 28 exists, by performing the aforementioned control, the intensity of the magnetic field generated by each antenna 28 can be uniformized, and therefore the plasma uniformity in the parallel direction Y of the antennas 28 can be improved.

Moreover, the aforementioned control can be performed in real time during generation of the plasma 50.

As a result, when the plasma processing apparatus of this embodiment is used, the uniformity of substrate processing in the longitudinal direction X of the antenna 28 can be improved as described above, and the plasma uniformity in the parallel direction Y of the antennas 28 can be improved as well. Hence, by combining the two effects, the uniformity of processing in two dimensions of the substrate surface can be enhanced without increasing the distance between the antenna 28 and the substrate 2.

Each antenna 28 is provided with multiple magnetic field sensors 90 respectively, and a combination (e.g. an average value) of the outputs of the multiple magnetic field sensors 90 of each antenna 28 is provided to the control device 100 respectively. The high frequency power outputted by each high frequency power supply 60 may be controlled, so as to make the combination value with respect to each antenna 28 substantially equal to each other.

Moreover, in the case of disposing multiple antennas 28 in parallel as described above, all the antennas 28 may be equally spaced, or the interval of two end regions in the parallel direction Y of the antennas 28 may be smaller than the interval of the other regions considering that the plasma density of the two end regions in the parallel direction Y of the antennas 28 tends to be lower than the plasma density of the other regions.

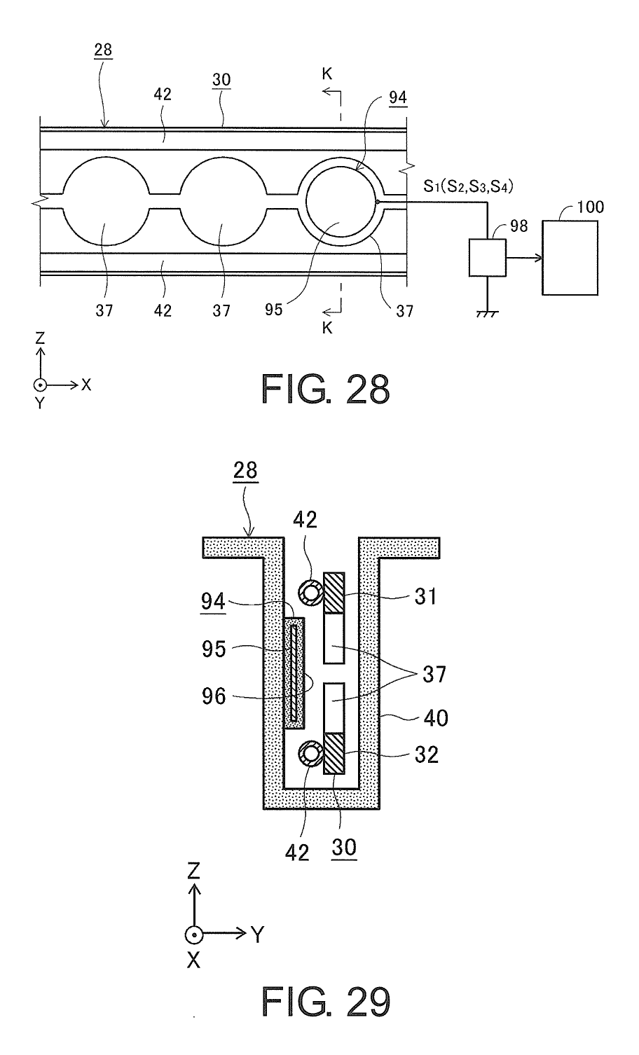

An electric field sensor 94 may be disposed in place of the magnetic field sensor 90, which is explained below with reference to FIG. 28 and FIG. 29. In FIG. 28, in order to illustrate an electrode plate 95 as the main element, a dielectric 96 is omitted. Details of the above are illustrated in FIG. 29.

Each electric field sensor 94 has a structure that the electrode plate 95 is covered by the dielectric 96. In the embodiment shown in FIG. 28, a planar shape of the electrode plate 95 is circular, but the planar shape may also have other shapes, such as rectangular, for example. Although the dielectric 96 is not a necessary element, it is preferable to dispose the dielectric 96. By doing so, even if the electric field sensor 94 is disposed near the high frequency electrode 30, discharge that may occur between the electrode plate 95 and the high frequency electrode 30 or the cooling pipe 42 can be prevented.

The electric field sensor 94 is disposed near the high frequency electrode 30 to be substantially parallel to the main surface of the high frequency electrode 30 (more specifically, the electrode plate 95 is substantially parallel to the main surface of the high frequency electrode 30). With such an arrangement, the output of the electric field sensor 94 is increased. In this arrangement, the electric field sensor 94 may be disposed at any location with respect to the high frequency electrode 30. However, since the highest potential is near the power feeding point 48 (see FIG. 5 and FIG. 6) of the high frequency electrode 30 and can be detected easily, it is preferable to dispose the electric field sensor 94 near the end portion on the side of the power feeding point 48. Nevertheless, in any case, the electric field sensors 94 are respectively disposed at substantially the same locations and in the same states with respect to the antennas 28 (more specifically, the high frequency electrode 30 thereof). Accordingly, the conditions for detection of the electric fields performed by the electric field sensors 94 can be uniformized.

As illustrated by the embodiment of FIG. 29, the electric field sensor 94 may be attached to the internal surface of the dielectric case 40, for example.

When supplying the high frequency power and applying the high frequency current I_{R} to each antenna 28 (more specifically, the high frequency electrode 30 thereof) as described above, given that the impedance of each high frequency electrode 30 is Z, a high frequency voltage V, represented by V=Z·I_{R}, is generated in the high frequency electrode 30. The magnitude of the high frequency voltage V is distributed along a current path of the high frequency electrode 30. The high frequency voltage V is a source of the electric field generated by each antenna 28. The high frequency voltage V, even if there is nearly no magnetic field generated by the antenna 28, also contributes to the generation of the plasma 50. It is called capacitive coupling. Accordingly, respectively detecting the field intensity, namely the high frequency voltage V generated by each antenna 28, and controlling to make the intensity substantially equal to each other also contributes to the improvement of the plasma uniformity in the parallel direction Y of the antennas 28.

In each electric field sensor 94 (more specifically, the electrode plate 95 thereof), a high frequency voltage corresponding to the magnitude of the high frequency voltage V is induced by capacitive coupling and is outputted as the output S₁ (or S₂, S₃, or S₄). The outputs S₁-S₄ may be supplied to the control device 100 directly, or the signal converter 98 may be disposed in the way for converting the outputs S₁-S₄ into signals that can be easily processed by the control device 100 (e.g. direct voltage) to be supplied to the control device 100.

The control device 100 controls the high frequency power outputted from each high frequency power supply 60 so as to make the outputs S₁-S₄ of the electric field sensors 94 (or the signals converted therefrom; the same hereinafter) substantially equal. For example, if the output of one electric field sensor 94 is smaller than the others, the high frequency power supplied to the antenna 28 to which this electric field sensor 94 is disposed is increased to make the output of this electric field sensor 94 equal to the other outputs, and vice versa.

By performing the aforementioned control, even if an impedance difference caused by the difference in temperature rise of the high frequency electrode 30 constituting each antenna 28 or an impedance difference in a high frequency power supply circuit to each antenna 28 exists, for example, the intensity of the magnetic field generated by each antenna 28 can be uniformized, and the plasma uniformity in the parallel direction Y of the antennas 28 can be improved.

Moreover, the aforementioned control can be performed in real time during generation of the plasma 50.

As a result, when the plasma processing apparatus of this embodiment is used, the uniformity of substrate processing in the longitudinal direction X of the antenna 28 can be improved as described above, and the plasma uniformity in the parallel direction Y of the antennas 28 can be improved as well. Hence, by combining the two effects, the uniformity of processing in two dimensions of the substrate surface can be enhanced without increasing the distance between the antenna 28 and the substrate 2.

Each antenna 28 is provided with multiple electric field sensors 94 respectively, and a combination (e.g. an average value) of the outputs of the multiple electric field sensors 94 of each antenna 28 is provided to the control device 100 respectively. The high frequency power outputted by each high frequency power supply 60 may be controlled, so as to make the combination value with respect to each antenna 28 substantially equal to each other.

Moreover, each antenna 28 may be provided with both the magnetic field sensor 90 and the electric field sensor 94 as aforementioned, and a combination of the outputs of the magnetic field sensor 90 and the electric field sensor 94 (e.g. a value weighted by a contribution ratio of the magnetic field and the electric field with respect to the plasma generation) is provided to the control device 100 respectively. The high frequency power outputted by each high frequency power supply 60 may be controlled, so as to make the combination value with respect to each antenna 28 substantially equal to each other.

Instead of disposing the high frequency power supply 60 at a position of the antenna 28 as illustrated in the embodiment of FIG. 25, a common high frequency power supply 60 and a distribution circuit 102 may be disposed as illustrated in the embodiment of FIG. 30. The following mainly explains the differences between the embodiment of FIG. 30 and the embodiment of FIG. 25. Details regarding the magnetic field sensor 90 and the electric field sensor 94 have been specified above and are therefore are repeated hereinafter.

The plasma processing apparatus shown in FIG. 30 includes the high frequency power supply 60 for supplying the high frequency power to each antenna 28, the distribution circuit 102 disposed between the high frequency power supply 60 and each antenna 28 for distributing the high frequency power outputted by the high frequency power supply 60 to each antenna 28, wherein the magnitude of the high frequency power distributed to each antenna 28 is variable responsive to an external control signal, a plurality of magnetic field sensors 90 as described above, and the control device 100 that controls the magnitude of the high frequency power distributed to each antenna 28 by the distribution circuit 102 responsive to the outputs of the magnetic field sensors 90 such that the outputs are substantially equal to each other. The entire output of the high frequency power supply 60 may be controlled by the control device 100.

The distribution circuit 102 may have a configuration including a plurality of variable impedances that are respectively inserted between the high frequency power supply 60 and the antennas 28 and are variable responsive to a control signal of the control device 100. Through control of the variable impedances, the magnitude of the high frequency power distributed to each antenna 28 can be controlled.

According to this embodiment, the magnitude of the high frequency power distributed to each antenna 28 by the distribution circuit 102 can be controlled responsive to the outputs of the magnetic field sensors 90 to make the outputs substantially equal to each other. Thus, even if an impedance difference caused by the difference in temperature rise of the high frequency electrode 30 constituting each antenna 28 or an impedance difference in a high frequency power supply circuit to each antenna 28 exists, for example, the intensity of the magnetic field generated by each antenna 28 can be uniformized, and the plasma uniformity in the parallel direction Y of the antennas 28 can be improved.

As a result, when the plasma processing apparatus of this embodiment is used, the uniformity of substrate processing in the longitudinal direction X of the antenna 28 can be improved as described above, and the plasma uniformity in the parallel direction Y of the antennas 28 can be improved as well. Hence, by combining the two effects, the uniformity of processing in two dimensions of the substrate surface can be enhanced without increasing the distance between the antenna 28 and the substrate 2.

The same as the embodiment of FIG. 25, the electric field sensor 94 may be disposed in place of the magnetic field sensor 90. In that case, the magnitude of the high frequency power distributed to each antenna 28 by the distribution circuit 102 can be controlled responsive to the outputs of the electric field sensors 94 to make the outputs substantially equal to each other. Thus, even if an impedance difference caused by the difference in temperature rise of the high frequency electrode 30 constituting each antenna 28 or an impedance difference in a high frequency power supply circuit to each antenna 28 exists, for example, the intensity of the electric field generated by each antenna 28 can be uniformized, and the plasma uniformity in the parallel direction Y of the antennas 28 can be improved.

As a result, the uniformity of substrate processing in the longitudinal direction X of the antenna 28 can be improved as described above, and the plasma uniformity in the parallel direction Y of the antennas 28 can be improved as well. Hence, by combining the two effects, the uniformity of processing in two dimensions of the substrate surface can be enhanced without increasing the distance between the antenna 28 and the substrate 2.

Moreover, each antenna 28 may be provided with both the magnetic field sensor 90 and the electric field sensor 94, and a combination of the outputs of the magnetic field sensor 90 and the electric field sensor 94 (e.g. a value weighted by a contribution ratio of the magnetic field and the electric field with respect to the plasma generation) is provided to the control device 100 respectively. The high frequency power distributed to each antenna 28 by the distribution circuit 102 may be controlled, so as to make the combination value with respect to each antenna 28 substantially equal to each other.

What is claimed is:

1. A plasma processing apparatus, which is an inductively-coupled plasma (ICP) type plasma processing apparatus adapted for generating an induced electric field in a vacuum container to generate a plasma by applying a high frequency current to an antenna and processing a substrate by using the plasma,
wherein the antenna comprises a structure that receives a high frequency electrode in a dielectric case,
the high frequency electrode comprises a go-and-return conductor structure that two electrode conductors, each comprising a rectangular plate shape, are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode, and
the antenna is disposed in the vacuum container in a direction that a main surface of the high frequency electrode that constitutes the antenna and a surface of the substrate are substantially perpendicular to each other.

2. A plasma processing apparatus, which is an inductively-coupled plasma (ICP) type plasma processing apparatus adapted for generating an induced electric field in a vacuum container to generate a plasma by applying a high frequency current to an antenna and processing a substrate by using the plasma,
wherein the antenna comprises a structure that receives a high frequency electrode in a dielectric case,
the high frequency electrode comprises a go-and-return conductor structure that two electrode conductors, one comprising a rectangular plate shape and the other comprising a rod shape, are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are formed on an edge of the electrode conductor comprising the rectangular plate shape on the side of the gap to form a plurality of openings that are dispersed and arranged in the longitudinal direction of the high frequency electrode, and
the antenna is disposed in the vacuum container in a direction that a main surface of the high frequency electrode that constitutes the antenna and a surface of the substrate are substantially perpendicular to each other.

3. The plasma processing apparatus according to claim 1, wherein the antenna comprises a planar shape that is substantially straight,
a plurality of the antennas are disposed in parallel to each other along the surface of the substrate, and
a power feeding point and a grounding point of the high frequency electrode that constitutes each antenna are respectively disposed on the same side of the plurality of antennas, and the grounding point is disposed on a side of the substrate.

4. The plasma processing apparatus according to claim 1, wherein the antenna comprises a planar shape that is substantially straight,
a plurality of the antennas are disposed in parallel to each other along the surface of the substrate, and
a power feeding point and a grounding point of the high frequency electrode that constitutes each antenna, are alternately disposed on the plurality of antennas.

5. The plasma processing apparatus according to claim 3, wherein an interval of two end regions in a parallel direction of the antennas is smaller than an interval of the other regions.

6. The plasma processing apparatus according to claim 1, wherein a planar shape of the antenna is annular.

7. The plasma processing apparatus according to claim 1, wherein the plurality of antennas are disposed to form an annular planar shape as a whole.

8. The plasma processing apparatus according to any of claims 1, wherein a plurality of dielectric tubes respectively pass through each of the openings of the high frequency electrode in the dielectric case so as to traverse the dielectric case.

9. The plasma processing apparatus according to any of claims 1, wherein a portion of at least one side surface of the dielectric case, which faces each opening of the high frequency electrode in the dielectric case, is partially recessed inward.

10. The plasma processing apparatus according to any of claims 1, wherein a region comprising a portion of at least one side surface of the dielectric case, which faces the openings of the high frequency electrode in the dielectric case, is continuously recessed inward along the longitudinal direction of the antenna.

11. The plasma processing apparatus according to claim 1, wherein the antenna comprises a structure that comprises two high frequency electrodes received in the dielectric case, and a cooling pipe, in which a coolant flows, is held between the two high frequency electrodes for cooling the two high frequency electrodes, and
distances respectively between an outer main surface of each high frequency electrode and an external surface of the dielectric case opposite thereto are made substantially equal to each other for the two high frequency electrodes.

12. The plasma processing apparatus according to claim 1, wherein the antenna comprises a structure that comprises two high frequency electrodes, and a cooling pipe, in which a coolant flows, is respectively attached to one main surface of each high frequency electrode for cooling the high frequency electrode, and the two high frequency electrodes are received in the dielectric case in a direction to put the cooling pipes on inner sides, and
distances respectively between an outer main surface of each high frequency electrode and an external surface of the dielectric case opposite thereto are made substantially equal to each other for the two high frequency electrodes.

13. The plasma processing apparatus according to claim 1, wherein the antenna comprises a structure that cooling pipes, in which a coolant flows, are respectively attached to two main surfaces of the high frequency electrode for cooling the high frequency electrode, and
distances respectively between the two main surfaces of the high frequency electrodes and external surfaces of the dielectric case opposite thereto are substantially equal to each other.

14. The plasma processing apparatus according to claim 1, wherein the high frequency electrode comprises a coolant passage therein, and a coolant flows in the coolant passage for cooling the high frequency electrode, and
distances respectively between two main surfaces of the high frequency electrodes and external surfaces of the dielectric case opposite thereto are substantially equal to each other.

15. A plasma processing apparatus, which is an inductively-coupled plasma (ICP) type plasma processing apparatus adapted for generating an induced electric field in a vacuum container to generate a plasma by applying a high frequency current to an antenna and processing a substrate by using the plasma,
wherein the antenna comprises a structure that receives a high frequency electrode in a dielectric case,
the high frequency electrode comprises a go-and-return conductor structure that two electrode conductors are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode,
the antenna is disposed in the vacuum container in a direction that a main surface of the high frequency electrode that constitutes the antenna and a surface of the substrate are substantially perpendicular to each other,
the two electrode conductors that constitute the two high frequency electrode are a pair of electrode conductors that are respectively bent to form a U-shaped cross-section, wherein two edges opposite to a bent portion of one of the electrode conductors and two edges opposite to a bent portion of the other one of the electrode conductors are disposed opposite to each other with the gap between, and the cutouts are formed on each of the edges to form the openings,
the antenna comprises a structure that a cooling pipe, which is respectively held between each bent electrode conductor and in which a coolant flows for cooling the high frequency electrode, is received in the dielectric case, and
distances respectively between two outer main surfaces of the high frequency electrode and external surfaces of the dielectric case opposite thereto are substantially equal to each other.

16. A plasma processing apparatus, which is an inductively-coupled plasma (ICP) type plasma processing apparatus adapted for generating an induced electric field in a vacuum container to generate a plasma by applying a high frequency current to an antenna and processing a substrate by using the plasma,
wherein the antenna comprises a structure that receives a high frequency electrode in a dielectric case,
the high frequency electrode comprises a go-and-return conductor structure that two electrode conductors are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode,
the antenna is disposed in the vacuum container in a direction that a main surface of the high frequency electrode that constitutes the antenna and a surface of the substrate are substantially perpendicular to each other,
the antenna comprises a planar shape that is substantially straight, and a plurality of the antennas are disposed in parallel along the surface of the substrate, and the plasma processing apparatus further comprises:
a plurality of high frequency power supplies respectively supplying a high frequency power to each antenna;
a plurality of magnetic field sensors respectively disposed at substantially the same location for each antenna and detecting an intensity of a magnetic field generated by each antenna; and
a control device controlling the high frequency power outputted by each high frequency power supply responsive to outputs from the magnetic field sensors so as to make the outputs substantially equal to each other.

17. A plasma processing apparatus, which is an inductively-coupled plasma (ICP) type plasma processing apparatus adapted for generating an induced electric field in a vacuum container to generate a plasma by applying a high frequency current to generate a plasma and processing a substrate by using the plasma,
wherein the antenna comprises a structure that receives a high frequency electrode in a dielectric case,
the high frequency electrode comprises a go-and-return conductor structure that two electrode conductors are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode,
the antenna is disposed in the vacuum container in a direction that a main surface of the high frequency electrode that constitutes the antenna and a surface of the substrate are substantially perpendicular to each other,
the antenna comprises a planar shape that is substantially straight, and a plurality of the antennas are disposed in parallel along the surface of the substrate, and the plasma processing apparatus further comprises:
a plurality of high frequency power supplies respectively supplying a high frequency power to each antenna;
a plurality of electric field sensors respectively disposed at substantially the same location for each antenna and detecting an intensity of an electric field generated by each antenna; and
a control device controlling the high frequency power outputted by each high frequency power supply responsive to outputs from the electric field sensors so as to make the outputs substantially equal to each other.

18. A plasma processing apparatus, which is an inductively-coupled plasma (ICP) type plasma processing apparatus adapted for generating an induced electric field in a vacuum container to an antenna by applying a high frequency current to an antenna and processing a substrate by using the plasma,
wherein the antenna comprises a structure that receives a high frequency electrode in a dielectric case,
the high frequency electrode comprises a go-and-return conductor structure that two electrode conductors are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode,
the antenna is disposed in the vacuum container in a direction that a main surface of the high frequency electrode that constitutes the antenna and a surface of the substrate are substantially perpendicular to each other,
the antenna comprises a planar shape that is substantially straight, and a plurality of the antennas are disposed in parallel along the surface of the substrate, and the plasma processing apparatus further comprises:
a high frequency power supply supplying a high frequency power to each antenna;
a distribution circuit disposed between the high frequency power supply and each antenna and distributing the high frequency power outputted by the high frequency power supply to each antenna, wherein a magnitude of the high frequency power distributed to each antenna is variable responsive to an external control signal;
a plurality of magnetic field sensors respectively disposed at substantially the same location for each antenna and detecting an intensity of a magnetic field generated by each antenna; and
a control device controlling the magnitude of the high frequency power distributed to each antenna by the distribution circuit responsive to outputs from the magnetic field sensors so as to make the outputs substantially equal to each other.

19. A plasma processing apparatus, which is an inductively-coupled plasma (ICP) type plasma processing apparatus adapted for generating an induced electric field in a vacuum container to generate a plasma by applying a high frequency current to an antenna and processing a substrate by using the plasma,
wherein the antenna comprises a structure that receives a high frequency electrode in a dielectric case,
the high frequency electrode comprises a go-and-return conductor structure that two electrode conductors are disposed close to and in parallel to each other with a gap therebetween to form a rectangular plate shape as a whole, and the two electrode conductors are connected by a conductor at one end in a longitudinal direction, wherein the high frequency current flows in opposite directions in the two electrode conductors, and a plurality of cutouts are respectively formed on edges of the two electrode conductors on the side of the gap to face each other across the gap so as to form a plurality of openings that are dispersed and arranged in the longitudinal direction of the high frequency electrode,
the antenna is disposed in the vacuum container in a direction that a main surface of the high frequency electrode that constitutes the antenna and a surface of the substrate are substantially perpendicular to each other,
the antenna comprises a planar shape that is substantially straight, and a plurality of the antennas are disposed in parallel along the surface of the substrate, and the plasma processing apparatus further comprises:
a high frequency power supply supplying a high frequency power to each antenna;
a distribution circuit disposed between the high frequency power supply and each antenna and distributing the high frequency power outputted by the high frequency power supply to each antenna, wherein a magnitude of the high frequency power distributed to each antenna is variable responsive to an external control signal;
a plurality of electric field sensors respectively disposed at substantially the same location for each antenna and detecting an intensity of an electric field generated by each antenna; and
a control device controlling the magnitude of the high frequency power distributed to each antenna by the distribution circuit responsive to outputs from the electric field sensors so as to make the outputs substantially equal to each other.
